(19) United States
(12) Patent Application Publication
(10) Pub. No.: US 2024/0419867 A1
(43) Pub. Date: Dec. 19, 2024

(54) DRILLING FRAMEWORK

(71) Applicant: Schlumberger Technology Corporation, Sugar Land, TX (US)

(72) Inventors: Alexey Ruzhnikov, Al-Khobar (SA); Peter Gregory, Cambridge (GB); Agustin Soriano Rementeria, Montpellier (FR); Michael John Williams, Cambridge (GB)

(21) Appl. No.: 18/817,309

(22) Filed: Aug. 28, 2024

Related U.S. Application Data
(63) Continuation of application No. 18/660,452, filed on May 10, 2024.
(60) Provisional application No. 63/466,150, filed on May 12, 2023.

(51) Int. Cl. G06F 30/20; G06F 30/12

(52) U.S. Cl. CPC G06F 30/20; G06F 30/12

(57) ABSTRACT

A system and method that include receiving data associated with a well at a field site. The system and method also include structuring the data as structured data according to an ontology of a computational knowledge system that is based at least in part on data from wells at other field sites. The system and method additionally include implementing the computational knowledge system to assess the structured data with respect to events. The system and method further include outputting an indicator of occurrence for at least one of the events for the well at the field site.

### RELATED APPLICATIONS

This application claims priority to U.S. application Ser. No. 18/660,452 filed 10 May 2024, which claims priority to and the benefit of a US Provisional Application having Ser. No. 63/466,150, filed 12 May 2023, both of which are incorporated by reference herein in its entirety.

### BACKGROUND

A reservoir may be a subsurface formation that may be characterized at least in part by its porosity and fluid permeability. As an example, a reservoir may be part of a basin such as a sedimentary basin. A basin may be a depression (e.g., caused by plate tectonic activity, subsidence, etc.) in which sediments accumulate. As an example, where hydrocarbon source rocks occur in combination with appropriate depth and duration of burial, a petroleum system may develop within a basin, which may form a reservoir that includes hydrocarbon fluids (e.g., oil, gas, etc.).

In oil and gas exploration, interpretation is a process that involves analysis of data to identify and locate various subsurface structures (e.g., horizons, faults, geobodies, etc.) in a geologic environment. Various types of structures (e.g., stratigraphic formations) may be indicative of hydrocarbon traps or flow channels, as may be associated with one or more reservoirs (e.g., fluid reservoirs). In the field of resource extraction, enhancements to interpretation may allow for construction of a more accurate model of a subsurface region, which, in turn, may improve characterization of the subsurface region for purposes of resource extraction. Characterization of one or more subsurface regions in a geologic environment may guide, for example, performance of one or more operations (e.g., field operations, etc.). As an example, a plan may depend on a model of a subsurface region where the plan may specify how a drilling operation may accurately construct a borehole according to a trajectory that penetrates a reservoir, etc., where fluid may be produced via the borehole (e.g., as a completed well, etc.). As an example, one or more workflows may be performed using one or more computational frameworks, systems, etc., for one or more of analysis, acquisition, model building, planning, control, exploration, interpretation, drilling, fracturing, production, etc.

### SUMMARY

According to one aspect, a method that includes receiving data associated with a well at a field site. The method also includes structuring the data as structured data according to an ontology of a computational knowledge system that is based at least in part on data from wells at other field sites. The method additionally includes implementing the computational knowledge system to assess the structured data with respect to events. The method further includes outputting an indicator of occurrence for at least one of the events for the well at the field site.

According to another aspect, a system may include one or more processors. The system also include memory accessible to at least one of the one or more processors. The system additionally includes processor-executable instructions stored in the memory and executable to instruct the system to receive data associated with a well at a field site, structure the data as structured data according to an ontology of a computational knowledge system that is based at least in part on data from wells at other field sites, implement the computational knowledge system to assess the structured data with respect to events, and output an indicator of occurrence for at least one of the events for the well at the field site.

According to yet another aspect, one or more computer-readable storage media comprising processor-executable instructions to instruct a computing system to receive data associated with a well at a field site. The instructions also include structuring the data as structured data according to an ontology of a computational knowledge system that is based at least in part on data from wells at other field sites. The instructions additionally include implementing the computational knowledge system to assess the structured data with respect to events. The instructions further include output an indicator of occurrence for at least one of the events for the well at the field site.

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

The following detailed description refers to the accompanying drawings. Wherever convenient Features and advantages of the described implementations may be more readily understood by reference to the following description taken in conjunction with the accompanying drawings.

FIG. 1 shows an example of a system;

FIG. 2 shows an example of a system;

FIG. 3 shows an example of a system;

FIG. 4 shows an example of a system;

FIG. 5 shows an example of a graphical user interface;

FIG. 6 shows an example of a graphical user interface;

FIG. 7 shows an example of a graphical user interface;

FIG. 8 shows an example of a graphical user interface;

FIG. 9 shows an example of a graphical user interface;

FIG. 10 shows an example of a workflow;

FIG. 11 shows an example of a table;

FIG. 12 shows an example of a system;

FIG. 13 shows an example of a graphical user interface;

FIG. 14 shows an example of a graphical user interface;

FIG. 15 shows an example of a graphical user interface;

FIG. 16 shows an example of a graphical user interface;

FIG. 17 shows an example of a method and an example of a system;

FIG. 18 shows an example of a method and an example of a system; and

FIG. 19 shows an example of a system.

### DETAILED DESCRIPTION

This description is not to be taken in a limiting sense, but rather is made merely for the purpose of describing the general principles of the implementations. The scope of the described implementations should be ascertained with reference to the issued claims.

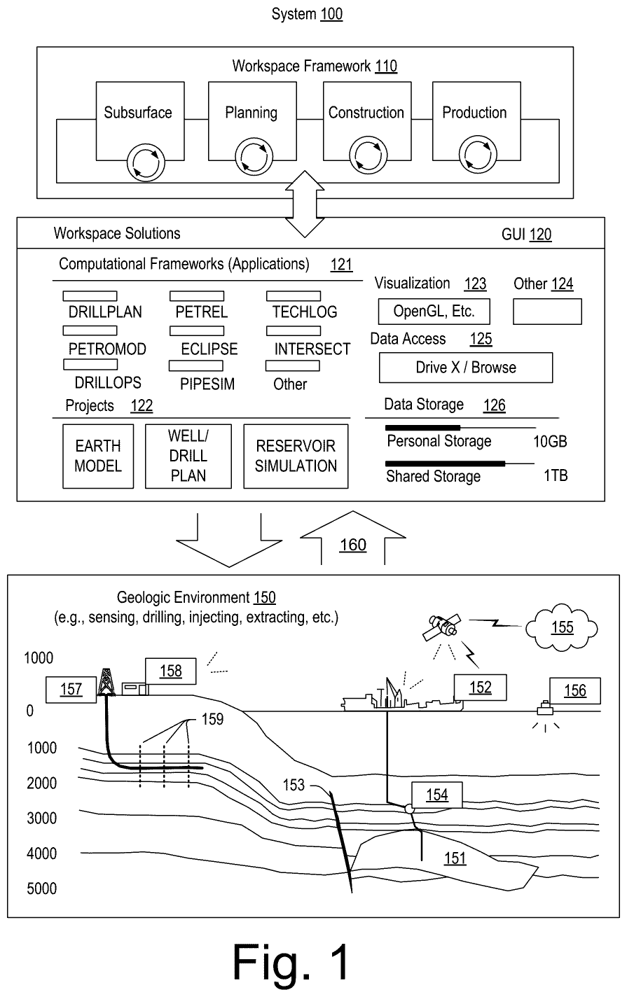

FIG. 1 shows an example of a system 100 that includes a workspace framework 110 that may provide for instantiation of, rendering of, interactions with, etc., a graphical user interface (GUI) 120. In the example of FIG. 1, the GUI 120 may include graphical controls for computational frameworks (e.g., applications, etc.) 121, projects 122, visualization 123, one or more other features 124, data access 125, and data storage 126.

In the example of FIG. 1, the workspace framework 110 may be tailored to a particular geologic environment such as an example geologic environment 150. For example, the geologic environment 150 may include layers (e.g., stratification) that include a reservoir 151 and that may be intersected by a fault 153. As an example, the geologic environment 150 may be outfitted with a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a wellsite and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or alternatively include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

In the example of FIG. 1, the GUI 120 shows some examples of computational frameworks, including the DRILLPLAN, DRILLOPS, PETREL, TECHLOG, PETROMOD, ECLIPSE, PIPESIM, and INTERSECT frameworks (SLB, Houston, Texas).

The DRILLPLAN framework provides for digital well construction planning and includes features for automation of repetitive tasks and validation workflows, enabling improved quality drilling programs (e.g., digital drilling plans, etc.) to be produced quickly with assured coherency.

The DRILLOPS framework may execute a digital drilling plan and ensures plan adherence, while delivering goal-based automation. The DRILLOPS framework may generate activity plans automatically individual operations, whether they are monitored and/or controlled on the rig or in town. Automation may utilize data analysis and learning systems to assist and optimize tasks, such as, for example, setting ROP to drilling a stand. A preset menu of automatable drilling tasks may be rendered, and, using data analysis and models, a plan may be executed in a manner to achieve a specified goal, where, for example, measurements may be utilized for calibration. The DRILLOPS framework provides flexibility to modify and replan activities dynamically, for example, based on a live appraisal of various factors (e.g., equipment, personnel, and supplies). Well construction activities (e.g., tripping, drilling, cementing, etc.) may be continually monitored and dynamically updated using feedback from operational activities. The DRILLOPS framework may provide for various levels of automation based on planning and/or re-planning (e.g., via the DRILLPLAN framework), feedback, etc.

The PETREL framework may be part of the DELFI environment for utilization in geosciences and geoengineering, for example, to analyze subsurface data from exploration to production of fluid from a reservoir. The DELFI cognitive exploration and production (E&P) environment (SLB, Houston, Texas), referred to herein as the DELFI environment or DELFI framework, is a secure, cognitive, cloud-based collaborative environment that integrates data and workflows with digital technologies, such as artificial intelligence and machine learning.

The PETREL framework provides components that allow for optimization of various exploration, development and production operations. The PETREL framework includes seismic to simulation software components that may output information for use in increasing reservoir performance, for example, by improving asset team productivity. Through use of such a framework, various professionals (e.g., geophysicists, geologists, and reservoir engineers) may develop collaborative workflows and integrate operations to streamline processes (e.g., with respect to one or more geologic environments, etc.). Such a framework may be considered an application (e.g., executable using one or more devices) and may be considered a data-driven application (e.g., where data is input for purposes of modeling, simulating, etc.).

The TECHLOG framework may handle and process field and laboratory data for a variety of geologic environments (e.g., deepwater exploration, shale, etc.). The TECHLOG framework may structure wellbore data for analyses, planning, etc.

The PETROMOD framework provides petroleum systems modeling capabilities that may combine one or more of seismic, well, and geological information to model the evolution of a sedimentary basin. The PETROMOD framework may predict if, and how, a reservoir has been charged with hydrocarbons, including the source and timing of hydrocarbon generation, migration routes, quantities, and hydrocarbon type in the subsurface or at surface conditions.

The ECLIPSE framework provides a reservoir simulator (e.g., as a computational framework) with numerical solutions for fast and accurate prediction of dynamic behavior for various types of reservoirs and development schemes.

The INTERSECT framework provides a high-resolution reservoir simulator for simulation of detailed geological features and quantification of uncertainties, for example, by creating accurate production scenarios and, with the integration of precise models of the surface facilities and field operations, the INTERSECT framework may produce reliable results, which may be continuously updated by real-time data exchanges (e.g., from one or more types of data acquisition equipment in the field that may acquire data during one or more types of field operations, etc.). The INTERSECT framework may provide completion configurations for complex wells where such configurations may be built in the field, may provide detailed enhanced-oil-recovery (EOR) formulations where such formulations may be implemented in the field, may analyze application of steam injection and other thermal EOR techniques for implementation in the field, advanced production controls in terms of reservoir coupling and flexible field management, and flexibility to script customized solutions for improved modeling and field management control. The INTERSECT framework, as with the other example frameworks, may be utilized as part of the DELFI environment, for example, for rapid simulation of multiple concurrent cases. For example, a workflow may utilize one or more of the DELFI environment on demand reservoir simulation features.

The aforementioned DELFI environment provides various features for workflows as to subsurface analysis, planning, construction and production, for example, as illustrated in the workspace framework 110. As shown in FIG. 1, outputs from the workspace framework 110 may be utilized for directing, controlling, etc., one or more processes in the geologic environment 150 and, feedback 160, may be received via one or more interfaces in one or more forms (e.g., acquired data as to operational conditions, equipment conditions, environment conditions, etc.).

As an example, a workflow may progress to a geology and geophysics (“G&G”) service provider, which may generate a well trajectory, which may involve execution of one or more G&G frameworks (e.g., consider the PETREL framework, etc.).

In the example of FIG. 1, the visualization features 123 may be implemented via the workspace framework 110, for example, to perform tasks as associated with one or more of subsurface regions, planning operations, constructing wells and/or surface fluid networks, and producing from a reservoir.

As an example, a visualization process may implement one or more of various features that may be suitable for one or more web applications. For example, a template may involve use of the JAVASCRIPT object notation format (JSON) and/or one or more other languages/formats. As an example, a framework may include one or more converters. For example, consider a JSON to PYTHON converter and/or a PYTHON to JSON converter. Such an approach may provide for compatibility of devices, frameworks, etc., with respect to one or more sets of instructions.

As an example, visualization features may provide for visualization of various earth models, properties, etc., in one or more dimensions. As an example, visualization features may provide for rendering of information in multiple dimensions, which may optionally include multiple resolution rendering. In such an example, information being rendered may be associated with one or more frameworks and/or one or more data stores. As an example, visualization features may include one or more control features for control of equipment, which may include, for example, field equipment that may perform one or more field operations. As an example, a workflow may utilize one or more frameworks to generate information that may be utilized to control one or more types of field equipment (e.g., drilling equipment, wireline equipment, fracturing equipment, etc.). As an example, generating a graphical user interface may include controlling a display device, for example, using instructions, which may be local instructions and/or transmitted instructions as may be transmitted via a wired and/or a wireless network from one device to another (e.g., consider a remote device).

As to a reservoir model that may be suitable for utilization by a simulator, consider acquisition of seismic data as acquired via reflection seismology, which finds use in geophysics, for example, to estimate properties of subsurface formations. As an example, reflection seismology may provide seismic data representing waves of elastic energy (e.g., as transmitted by P-waves and S-waves, in a frequency range of approximately 1 Hz to approximately 100 Hz). Seismic data may be processed and interpreted, for example, to understand better composition, fluid content, extent and geometry of subsurface rocks. Such interpretation results may be utilized to plan, simulate, perform, etc., one or more operations for production of fluid from a reservoir (e.g., reservoir rock, etc.).

Field acquisition equipment may be utilized to acquire seismic data, which may be in the form of traces where a trace may include values organized with respect to time and/or depth (e.g., consider 1D, 2D, 3D or 4D seismic data). For example, consider acquisition equipment that acquires digital samples at a rate of one sample per approximately 4 ms. Given a speed of sound in a medium or media, a sample rate may be converted to an approximate distance. For example, the speed of sound in rock may be on the order of around 5 km per second. Thus, a sample time spacing of approximately 4 ms would correspond to a sample “depth” spacing of about 10 meters (e.g., assuming a path length from source to boundary and boundary to sensor). As an example, a trace may be about 4 seconds in duration; thus, for a sampling rate of one sample at about 4 ms intervals, such a trace would include about 1000 samples where latter acquired samples correspond to deeper reflection boundaries. If the 4 second trace duration of the foregoing example is divided by two (e.g., to account for reflection), for a vertically aligned source and sensor, a deepest boundary depth may be estimated to be about 10 km (e.g., assuming a speed of sound of about 5 km per second).

As an example, a model may be a simulated version of a geologic environment. As an example, a simulator may include features for simulating physical phenomena in a geologic environment based at least in part on a model or models. A simulator, such as a reservoir simulator, may simulate fluid flow in a geologic environment based at least in part on a model that may be generated via a framework that receives seismic data. A simulator may be a computerized system (e.g., a computing system) that may execute instructions using one or more processors to solve a system of equations that describe physical phenomena subject to various constraints. In such an example, the system of equations may be spatially defined (e.g., numerically discretized) according to a spatial model that that includes layers of rock, geobodies, etc., that have corresponding positions that may be based on interpretation of seismic and/or other data. A spatial model may be a cell-based model where cells are defined by a grid (e.g., a mesh). A cell in a cell-based model may represent a physical area or volume in a geologic environment where the cell may be assigned physical properties (e.g., permeability, fluid properties, etc.) that may be germane to one or more physical phenomena (e.g., fluid volume, fluid flow, pressure, etc.). A reservoir simulation model may be a spatial model that may be cell-based.

A simulator may be utilized to simulate the exploitation of a real reservoir, for example, to examine different productions scenarios to find an optimal one before production or further production occurs. A reservoir simulator does not provide an exact replica of flow in and production from a reservoir at least in part because the description of the reservoir and the boundary conditions for the equations for flow in a porous rock are generally known with an amount of uncertainty. Certain types of physical phenomena occur at a spatial scale that may be relatively small compared to size of a field. A balance may be struck between model scale and computational resources that results in model cell sizes being of the order of meters; rather than a lesser size (e.g., a level of detail of pores). A modeling and simulation workflow for multiphase flow in porous media (e.g., reservoir rock, etc.) may include generalizing real micro-scale data from macro scale observations (e.g., seismic data and well data) and upscaling to a manageable scale and problem size. Uncertainties may exist in input data and solution procedure such that simulation results too are to some extent uncertain. A process known as history matching may involve comparing simulation results to actual field data acquired during production of fluid from a field. Information gleaned from history matching, may provide for adjustments to a model, data, etc., which may help to increase accuracy of simulation.

As an example, a simulator may utilize various types of constructs, which may be referred to as entities. Entities may include earth entities or geological objects such as wells, surfaces, reservoirs, etc. Entities may include virtual representations of actual physical entities that may be reconstructed for purposes of simulation. Entities may include entities based on data acquired via sensing, observation, etc. (e.g., consider entities based at least in part on seismic data and/or other information). As an example, an entity may be characterized by one or more properties (e.g., a geometrical pillar grid entity of an earth model may be characterized by a porosity property, etc.). Such properties may represent one or more measurements (e.g., acquired data), calculations, etc.

As an example, a simulator may utilize an object-based software framework, which may include entities based on pre-defined classes to facilitate modeling and simulation. As an example, an object class may encapsulate reusable code and associated data structures. Object classes may be used to instantiate object instances for use by a program, script, etc. For example, borehole classes may define objects for representing boreholes based on well data. A model of a basin, a reservoir, etc. may include one or more boreholes where a borehole may be, for example, for measurements, injection, production, etc. As an example, a borehole may be a wellbore of a well, which may be a completed well (e.g., for production of a resource from a reservoir, for injection of material, etc.).

While several simulators are illustrated in the example of FIG. 1, one or more other simulators may be utilized, additionally or alternatively. For example, consider the VISAGE geomechanics simulator (SLB, Houston Texas) or the PIPESIM network simulator (SLB, Houston Texas), etc. The VISAGE simulator includes finite element numerical solvers that may provide simulation results such as, for example, results as to compaction and subsidence of a geologic environment, well and completion integrity in a geologic environment, cap-rock and fault-seal integrity in a geologic environment, fracture behavior in a geologic environment, thermal recovery in a geologic environment, CO2 disposal, etc. The PIPESIM simulator includes solvers that may provide simulation results such as, for example, multiphase flow results (e.g., from a reservoir to a wellhead and beyond, etc.), flowline and surface facility performance, etc. The PIPESIM simulator may be integrated, for example, with the AVOCET production operations framework (SLB, Houston Texas). As an example, a reservoir or reservoirs may be simulated with respect to one or more enhanced recovery techniques (e.g., consider a thermal process such as steam-assisted gravity drainage (SAGD), etc.). As an example, the PIPESIM simulator may be an optimizer that may optimize one or more operational scenarios at least in part via simulation of physical phenomena. The MANGROVE simulator (SLB, Houston, Texas) provides for optimization of stimulation design (e.g., stimulation treatment operations such as hydraulic fracturing) in a reservoir-centric environment. The MANGROVE framework may combine scientific and experimental work to predict geomechanical propagation of hydraulic fractures, reactivation of natural fractures, etc., along with production forecasts within 3D reservoir models (e.g., production from a drainage area of a reservoir where fluid moves via one or more types of fractures to a well and/or from a well). The MANGROVE framework may provide results pertaining to heterogeneous interactions between hydraulic and natural fracture networks, which may assist with optimization of the number and location of fracture treatment stages (e.g., stimulation treatment(s)), for example, to increased perforation efficiency and recovery.

As an example, data may include geochemical data. For example, consider data acquired using X-ray fluorescence (XRF) technology, Fourier transform infrared spectroscopy (FTIR) technology and/or wireline geochemical technology.

As an example, one or more probes may be deployed in a bore via a wireline or wirelines. As an example, a probe may emit energy and receive energy where such energy may be analyzed to help determine mineral composition of rock surrounding a bore. As an example, nuclear magnetic resonance may be implemented (e.g., via a wireline, downhole NMR probe, etc.), for example, to acquire data as to nuclear magnetic properties of elements in a formation (e.g., hydrogen, carbon, phosphorous, etc.).

As an example, lithology scanning technology may be employed to acquire and analyze data. For example, consider the LITHO SCANNER technology (SLB, Houston, Texas). As an example, a LITHO SCANNER tool may be or include a gamma ray spectroscopy tool.

As an example, a tool may be positioned to acquire information in a portion of a borehole. Analysis of such information may reveal vugs, dissolution planes (e.g., dissolution along bedding planes), stress-related features, dip events, etc. As an example, a tool may acquire information that may help to characterize a fractured reservoir, optionally where fractures may be natural and/or artificial (e.g., hydraulic fractures). Such information may assist with completions, stimulation treatment, etc. As an example, information acquired by a tool may be analyzed using a framework such as the aforementioned TECHLOG framework.

As an example, a workflow may utilize one or more types of data for one or more processes (e.g., stratigraphic modeling, basin modeling, completion designs, drilling, production, injection, etc.). As an example, one or more tools may provide data that may be used in a workflow or workflows that may implement one or more frameworks (e.g., PETREL, TECHLOG, PETROMOD, ECLIPSE, etc.).

In the example of FIG. 1, drilling may be performed in the geologic environment 150, for example, to access the reservoir 151, which may be accessed from land or offshore. In FIG. 1, the downhole equipment 154 may be, for example, part of a bottom hole assembly (BHA). The BHA may be used to drill a well. The downhole equipment 154 may communicate information to equipment at the surface, and may receive instructions and information from the equipment at the surface. During a well construction process, a variety of operations (such as cementing, wireline evaluation, testing, etc.) may be conducted. In such embodiments, data collected by tools and sensors and used for reasons such as reservoir characterization may be collected and transmitted.

A well may include a substantially horizontal portion (e.g., lateral portion) that may intersect with one or more fractures. For example, a well in a shale formation may pass through natural fractures, artificial fractures (e.g., hydraulic fractures), or a combination thereof. Such a well may be constructed using directional drilling techniques as described herein. However, these same techniques may be used in connection with other types of directional wells (such as slant wells, S-shaped wells, deep inclined wells, and others) and are not limited to horizontal wells.

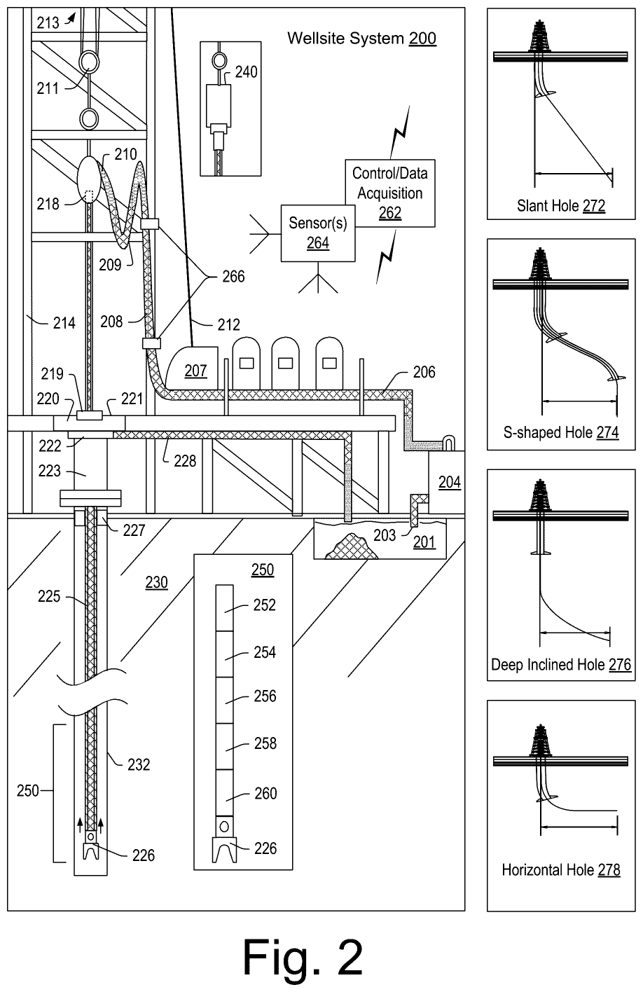

FIG. 2 shows an example of a wellsite system 200 (e.g., at a wellsite that may be onshore or offshore). As shown, the wellsite system 200 may include a mud tank 201 for holding mud and other material (e.g., where mud may be a drilling fluid), a suction line 203 that serves as an inlet to a mud pump 204 for pumping mud from the mud tank 201 such that mud flows to a vibrating hose 206, a drawworks 207 for winching drill line or drill lines 212, a standpipe 208 that receives mud from the vibrating hose 206, a kelly hose 209 that receives mud from the standpipe 208, a gooseneck or goosenecks 210, a traveling block 211, a crown block 213 for carrying the traveling block 211 via the drill line or drill lines 212, a derrick 214, a kelly 218 or a top drive 240, a kelly drive bushing 219, a rotary table 220, a drill floor 221, a bell nipple 222, one or more blowout preventors (BOPs) 223, a drillstring 225, a drill bit 226, a casing head 227 and a flow pipe 228 that carries mud and other material to, for example, the mud tank 201.

In the example system of FIG. 2, a borehole 232 is formed in subsurface formations 230 by rotary drilling; noting that various example embodiments may also use one or more directional drilling techniques, equipment, etc.

As shown in the example of FIG. 2, the drillstring 225 is suspended within the borehole 232 and has a drillstring assembly 250 that includes the drill bit 226 at its lower end. As an example, the drillstring assembly 250 may be a bottom hole assembly (BHA).

The wellsite system 200 may provide for operation of the drillstring 225 and other operations. As shown, the wellsite system 200 includes the traveling block 211 and the derrick 214 positioned over the borehole 232. As mentioned, the wellsite system 200 may include the rotary table 220 where the drillstring 225 pass through an opening in the rotary table 220.

As shown in the example of FIG. 2, the wellsite system 200 may include the kelly 218 and associated components, etc., or a top drive 240 and associated components. As to a kelly example, the kelly 218 may be a square or hexagonal metal/alloy bar with a hole drilled therein that serves as a mud flow path. The kelly 218 may be used to transmit rotary motion from the rotary table 220 via the kelly drive bushing 219 to the drillstring 225, while allowing the drillstring 225 to be lowered or raised during rotation. The kelly 218 may pass through the kelly drive bushing 219, which may be driven by the rotary table 220. As an example, the rotary table 220 may include a master bushing that operatively couples to the kelly drive bushing 219 such that rotation of the rotary table 220 may turn the kelly drive bushing 219 and hence the kelly 218. The kelly drive bushing 219 may include an inside profile matching an outside profile (e.g., square, hexagonal, etc.) of the kelly 218; however, with slightly larger dimensions so that the kelly 218 may freely move up and down inside the kelly drive bushing 219.

As to a top drive example, the top drive 240 may provide functions performed by a kelly and a rotary table. The top drive 240 may turn the drillstring 225. As an example, the top drive 240 may include one or more motors (e.g., electric and/or hydraulic) connected with appropriate gearing to a short section of pipe called a quill, that in turn may be screwed into a saver sub or the drillstring 225 itself. The top drive 240 may be suspended from the traveling block 211, so the rotary mechanism is free to travel up and down the derrick 214. As an example, a top drive 240 may allow for drilling to be performed with more joint stands than a kelly/rotary table approach.

In the example of FIG. 2, the mud tank 201 may hold mud, which may be one or more types of drilling fluids. As an example, a wellbore may be drilled to produce fluid, inject fluid or both (e.g., hydrocarbons, minerals, water, etc.).

In the example of FIG. 2, the drillstring 225 (e.g., including one or more downhole tools) may be composed of a series of pipes threadably connected together to form a long tube with the drill bit 226 at the lower end thereof. As the drillstring 225 is advanced into a wellbore for drilling, at some point in time prior to or coincident with drilling, the mud may be pumped by the pump 204 from the mud tank 201 (e.g., or other source) via the lines 206, 208 and 209 to a port of the kelly 218 or, for example, to a port of the top drive 240. The mud may then flow via a passage (e.g., or passages) in the drillstring 225 and out of ports located on the drill bit 226 (see, e.g., a directional arrow). As the mud exits the drillstring 225 via ports in the drill bit 226, it may then circulate upwardly through an annular region between an outer surface(s) of the drillstring 225 and surrounding wall(s) (e.g., open borehole, casing, etc.), as indicated by directional arrows. In such a manner, the mud lubricates the drill bit 226 and carries heat energy (e.g., frictional or other energy) and formation cuttings to the surface where the mud (e.g., and cuttings) may be returned to the mud tank 201, for example, for recirculation (e.g., with processing to remove cuttings, etc.).

The mud pumped by the pump 204 into the drillstring 225 may, after exiting the drillstring 225, form a mudcake that lines the wellbore which, among other functions, may reduce friction between the drillstring 225 and surrounding wall(s) (e.g., borehole, casing, etc.). A reduction in friction may facilitate advancing or retracting the drillstring 225. During a drilling operation, the entire drillstring 225 may be pulled from a wellbore and optionally replaced, for example, with a new or sharpened drill bit, a smaller diameter drillstring, etc. As mentioned, the act of pulling a drillstring out of a hole or replacing it in a hole is referred to as tripping. A trip may be referred to as an upward trip or an outward trip or as a downward trip or an inward trip depending on trip direction.

As an example, consider a downward trip where upon arrival of the drill bit 226 of the drillstring 225 at a bottom of a wellbore, pumping of the mud commences to lubricate the drill bit 226 for purposes of drilling to enlarge the wellbore. As mentioned, the mud may be pumped by the pump 204 into a passage of the drillstring 225 and, upon filling of the passage, the mud may be used as a transmission medium to transmit energy, for example, energy that may encode information as in mud-pulse telemetry.

As an example, mud-pulse telemetry equipment may include a downhole device configured to effect changes in pressure in the mud to create an acoustic wave or waves upon which information may modulated. In such an example, information from downhole equipment (e.g., one or more modules of the drillstring 225) may be transmitted uphole to an uphole device, which may relay such information to other equipment for processing, control, etc.

As an example, telemetry equipment may operate via transmission of energy via the drillstring 225 itself. For example, consider a signal generator that imparts coded energy signals to the drillstring 225 and repeaters that may receive such energy and repeat it to further transmit the coded energy signals (e.g., information, etc.).

As an example, the drillstring 225 may be fitted with telemetry equipment 252 that includes a rotatable drive shaft, a turbine impeller mechanically coupled to the drive shaft such that the mud may cause the turbine impeller to rotate, a modulator rotor mechanically coupled to the drive shaft such that rotation of the turbine impeller causes said modulator rotor to rotate, a modulator stator mounted adjacent to or proximate to the modulator rotor such that rotation of the modulator rotor relative to the modulator stator creates pressure pulses in the mud, and a controllable brake for selectively braking rotation of the modulator rotor to modulate pressure pulses. In such an example, an alternator may be coupled to the aforementioned drive shaft where the alternator includes at least one stator winding electrically coupled to a control circuit to selectively short the at least one stator winding to electromagnetically brake the alternator and thereby selectively brake rotation of the modulator rotor to modulate the pressure pulses in the mud.

In the example of FIG. 2, an uphole control and/or data acquisition system 262 may include circuitry to sense pressure pulses generated by telemetry equipment 252 and, for example, communicate sensed pressure pulses or information derived therefrom for process, control, etc.

The assembly 250 of the illustrated example includes a logging-while-drilling (LWD) module 254, a measurement-while-drilling (MWD) module 256, an optional module 258, a rotary-steerable system (RSS) and/or motor 260, and the drill bit 226. Such components or modules may be referred to as tools where a drillstring may include a plurality of tools.

As to an RSS, it involves technology utilized for directional drilling. Directional drilling involves drilling into the Earth to form a deviated bore such that the trajectory of the bore is not vertical; rather, the trajectory deviates from vertical along one or more portions of the bore. As an example, consider a target that is located at a lateral distance from a surface location where a rig may be stationed. In such an example, drilling may commence with a vertical portion and then deviate from vertical such that the bore is aimed at the target and, eventually, reaches the target. Directional drilling may be implemented where a target may be inaccessible from a vertical location at the surface of the Earth, where material exists in the Earth that may impede drilling or otherwise be detrimental (e.g., consider a salt dome, etc.), where a formation is laterally extensive (e.g., consider a relatively thin yet laterally extensive reservoir), where multiple bores are to be drilled from a single surface bore, where a relief well is desired, etc.

One approach to directional drilling involves a mud motor; however, a mud motor may present some challenges depending on factors such as rate of penetration (ROP), transferring weight to a bit (e.g., weight on bit, WOB) due to friction, etc. A mud motor may be a positive displacement motor (PDM) that operates to drive a bit (e.g., during directional drilling, etc.). A PDM operates as drilling fluid is pumped through it where the PDM converts hydraulic power of the drilling fluid into mechanical power to cause the bit to rotate.

As an example, a mud motor (e.g., PDM) may be operated in different modes, which may include a rotating mode and a sliding mode. A sliding mode involves drilling with a mud motor rotating the bit downhole without rotating the drillstring from the surface. Such an operation may be conducted when a BHA has been fitted with a bent sub or a bent housing mud motor, or both, for directional drilling. Sliding may be used in building and controlling or adjusting hole angle. In directional drilling, pointing of a bit may be accomplished through a bent sub, which may have a relatively small angle offset from the axis of a drillstring, and a measurement device to determine the direction of offset. Without turning the drillstring, the bit may be rotated with mud flow through the mud motor to drill in the direction it is pointed. With steerable motors, when a desired wellbore direction is attained, the entire drillstring may be rotated to drill straight rather than at an angle. By controlling the amount of hole drilled in the sliding mode versus the rotating mode, a wellbore trajectory may be controlled rather precisely.

As an example, a PDM may operate in a combined rotating mode where surface equipment is utilized to rotate a bit of a drillstring (e.g., a rotary table, a top drive, etc.) by rotating the entire drillstring and where drilling fluid is utilized to rotate the bit of the drillstring. In such an example, a surface RPM (SRPM) may be determined by use of the surface equipment and a downhole RPM of the mud motor may be determined using various factors related to flow of drilling fluid, mud motor type, etc. As an example, in the combined rotating mode, bit RPM may be determined or estimated as a sum of the SRPM and the mud motor RPM, assuming the SRPM and the mud motor RPM are in the same direction.

As an example, a PDM mud motor may operate in a so-called sliding mode, when the drillstring is not rotated from the surface. In such an example, a bit RPM may be determined or estimated based on the RPM of the mud motor.

An RSS may drill directionally where there is continuous rotation from surface equipment, which may alleviate the sliding of a steerable motor (e.g., a PDM). An RSS may be deployed when drilling directionally (e.g., deviated, horizontal, or extended-reach wells). An RSS may aim to minimize interaction with a borehole wall, which may help to preserve borehole quality. An RSS may aim to exert a relatively consistent side force akin to stabilizers that rotate with the drillstring or orient the bit in the desired direction while continuously rotating at the same number of rotations per minute as the drillstring.

The LWD module 254 may be housed in a suitable type of drill collar and may contain one or a plurality of selected types of logging tools. It will also be understood that more than one LWD and/or MWD module may be employed. Where the position of an LWD module 254 is mentioned, as an example, it may refer to a module at the position of the LWD module 254, the MWD module 256, etc. An LWD module may include capabilities for measuring, processing, and storing information, as well as for communicating with the surface equipment. In the illustrated example, the LWD module 254 may include a seismic measuring device.

The MWD module 256 may be housed in a suitable type of drill collar and may contain one or more devices for measuring characteristics of the drillstring 225 and the drill bit 226. As an example, the MWD module 256 may include equipment for generating electrical power, for example, to power various components of the drillstring 225. As an example, the MWD module 256 may include the telemetry equipment 252, for example, where the turbine impeller may generate power by flow of the mud; it being understood that other power and/or battery systems may be employed for purposes of powering various components. As an example, the MWD module 256 may include one or more of the following types of measuring devices: a weight-on-bit measuring device, a torque measuring device, a vibration measuring device, a shock measuring device, a stick slip measuring device, a direction measuring device, and an inclination measuring device.

FIG. 2 also shows some examples of types of holes that may be drilled. For example, consider a slant hole 272, an S-shaped hole 274, a deep inclined hole 276 and a horizontal hole 278.

As an example, a drilling operation may include directional drilling where, for example, at least a portion of a well includes a curved axis. For example, consider a radius that defines curvature where an inclination with regard to the vertical may vary until reaching an angle between about 30 degrees and about 60 degrees or, for example, an angle to about 90 degrees or possibly greater than about 90 degrees.

As an example, a directional well may include several shapes where each of the shapes may aim to meet particular operational demands. As an example, a drilling process may be performed on the basis of information as and when it is relayed to a drilling engineer. As an example, inclination and/or direction may be modified based on information received during a drilling process.

As an example, deviation of a bore may be accomplished in part by use of a downhole motor and/or a turbine. As to a motor, for example, a drillstring may include a positive displacement motor (PDM).

As an example, a system may be a steerable system and include equipment to perform method such as geosteering. As mentioned, a steerable system may be or include an RSS. As an example, a steerable system may include a PDM or of a turbine on a lower part of a drillstring which, just above a drill bit, a bent sub may be mounted. As an example, above a PDM, MWD equipment that provides real time or near real time data of interest (e.g., inclination, direction, pressure, temperature, real weight on the drill bit, torque stress, etc.) and/or LWD equipment may be installed. As to the latter, LWD equipment may make it possible to send to the surface various types of data of interest, including for example, geological data (e.g., gamma ray log, resistivity, density and sonic logs, etc.).

The coupling of sensors providing information on the course of a well trajectory, in real time or near real time, with, for example, one or more logs characterizing the formations from a geological viewpoint, may allow for implementing a geosteering method. Such a method may include navigating a subsurface environment, for example, to follow a desired route to reach a desired target or targets.

As an example, a drillstring may include an azimuthal density neutron (ADN) tool for measuring density and porosity; a MWD tool for measuring inclination, azimuth and shocks; a compensated dual resistivity (CDR) tool for measuring resistivity and gamma ray related phenomena; one or more variable gauge stabilizers; one or more bend joints; and a geosteering tool, which may include a motor and optionally equipment for measuring and/or responding to one or more of inclination, resistivity and gamma ray related phenomena.

As an example, geosteering may include intentional directional control of a wellbore based on results of downhole geological logging measurements in a manner that aims to keep a directional wellbore within a desired region, zone (e.g., a pay zone), etc. As an example, geosteering may include directing a wellbore to keep the wellbore in a particular section of a reservoir, for example, to minimize gas and/or water breakthrough and, for example, to maximize economic production from a well that includes the wellbore.

Referring again to FIG. 2, the wellsite system 200 may include one or more sensors 264 that are operatively coupled to the control and/or data acquisition system 262. As an example, a sensor or sensors may be at surface locations. As an example, a sensor or sensors may be at downhole locations. As an example, a sensor or sensors may be at one or more remote locations that are not within a distance of the order of about one hundred meters from the wellsite system 200. As an example, a sensor or sensor may be at an offset wellsite where the wellsite system 200 and the offset wellsite are in a common field (e.g., oil and/or gas field).

As an example, one or more of the sensors 264 may be provided for tracking pipe, tracking movement of at least a portion of a drillstring, etc.

As an example, the system 200 may include one or more sensors 266 that may sense and/or transmit signals to a fluid conduit such as a drilling fluid conduit (e.g., a drilling mud conduit). For example, in the system 200, the one or more sensors 266 may be operatively coupled to portions of the standpipe 208 through which mud flows. As an example, a downhole tool may generate pulses that may travel through the mud and be sensed by one or more of the one or more sensors 266. In such an example, the downhole tool may include associated circuitry such as, for example, encoding circuitry that may encode signals, for example, to reduce demands as to transmission. As an example, circuitry at the surface may include decoding circuitry to decode encoded information transmitted at least in part via mud-pulse telemetry. As an example, circuitry at the surface may include encoder circuitry and/or decoder circuitry and circuitry downhole may include encoder circuitry and/or decoder circuitry. As an example, the system 200 may include a transmitter that may generate signals that may be transmitted downhole via mud (e.g., drilling fluid) as a transmission medium.

As an example, one or more portions of a drillstring may become stuck. The term stuck may refer to one or more of varying degrees of inability to move or remove a drillstring from a bore. As an example, in a stuck condition, it might be possible to rotate pipe or lower it back into a bore or, for example, in a stuck condition, there may be an inability to move the drillstring axially in the bore, though some amount of rotation may be possible. As an example, in a stuck condition, there may be an inability to move at least a portion of the drillstring axially and rotationally.

As to the term “stuck pipe”, this may refer to a portion of a drillstring that cannot be rotated or moved axially. As an example, a condition referred to as “differential sticking” may be a condition whereby the drillstring cannot be moved (e.g., rotated or reciprocated) along the axis of the bore. Differential sticking may occur when high-contact forces caused by low reservoir pressures, high wellbore pressures, or both, are exerted over a sufficiently large area of the drillstring. Differential sticking may have time and financial cost.

As an example, a sticking force may be a product of the differential pressure between the wellbore and the reservoir and the area that the differential pressure is acting upon. This means that a relatively low differential pressure (delta p) applied over a large working area may be just as effective in sticking pipe as may a high differential pressure applied over a small area.

As an example, a condition referred to as “mechanical sticking” may be a condition where limiting or prevention of motion of the drillstring by a mechanism other than differential pressure sticking occurs. Mechanical sticking may be caused, for example, by one or more of junk in the hole, wellbore geometry anomalies, cement, keyseats or a buildup of cuttings in the annulus.

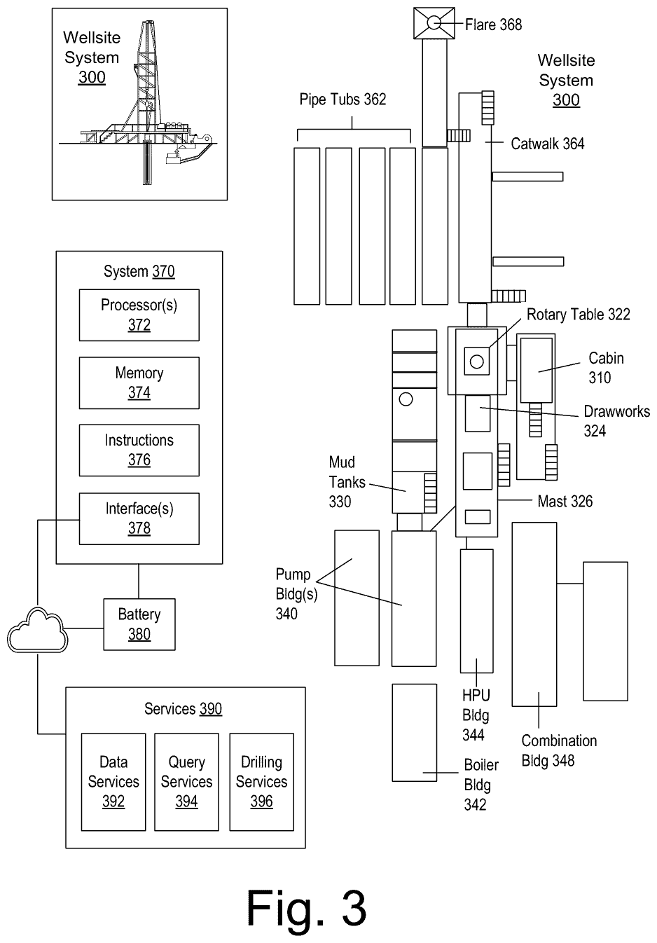

FIG. 3 shows an example of a wellsite system 300, specifically, FIG. 3 shows the wellsite system 300 in an approximate side view and an approximate plan view along with a block diagram of a system 370.

In the example of FIG. 3, the wellsite system 300 may include a cabin 310, a rotary table 322, drawworks 324, a mast 326 (e.g., optionally carrying a top drive, etc.), mud tanks 330 (e.g., with one or more pumps, one or more shakers, etc.), one or more pump buildings 340, a boiler building 342, an HPU building 344 (e.g., with a rig fuel tank, etc.), a combination building 348 (e.g., with one or more generators, etc.), pipe tubs 362, a catwalk 364, a flare 368, etc. Such equipment may include one or more associated functions and/or one or more associated operational risks, which may be risks as to time, resources, and/or humans.

As shown in the example of FIG. 3, the wellsite system 300 may include a system 370 that includes one or more processors 372, memory 374 operatively coupled to at least one of the one or more processors 372, instructions 376 that may be, for example, stored in the memory 374, and one or more interfaces 378. As an example, the system 370 may include one or more processor-readable media that include processor-executable instructions executable by at least one of the one or more processors 372 to cause the system 370 to control one or more aspects of the wellsite system 300. In such an example, the memory 374 may be or include the one or more processor-readable media where the processor-executable instructions may be or include instructions. As an example, a processor-readable medium may be a computer-readable storage medium that is not a signal and that is not a carrier wave.

FIG. 3 also shows a battery 380 that may be operatively coupled to the system 370, for example, to power the system 370. As an example, the battery 380 may be a back-up battery that operates when another power supply is unavailable for powering the system 370. As an example, the battery 380 may be operatively coupled to a network, which may be a cloud network. As an example, the battery 380 may include smart battery circuitry and may be operatively coupled to one or more pieces of equipment via a SMBus or other type of bus.

In the example of FIG. 3, services 390 are shown as being available, for example, via a cloud platform. Such services may include data services 392, query services 394 and drilling services 396. As an example, the services 390 may be part of a system such as the system 100 of FIG. 1 (e.g., consider planning services and/or operational services). As an example, the services 390 may include one or more services for directional drilling (e.g., consider a computational framework that may provide for one or more services that utilize real-time data to estimate one or more parameters, etc.).

As an example, the system 370 may be utilized to generate one or more rate of penetration drilling parameter values, which may, for example, be utilized to control one or more drilling operations.

As an example, a method may include automating operations of one or more types of downhole tools. For example, consider automating operations of one or more of mud motors, rotary steerable systems (RSSs) and at-bit steerable systems (ABSSs). As an example, one or more of such types of equipment, systems, etc., may be implemented using one or more features of the system 200 of FIG. 2.

As an example, an ABSS may include an actuator with a pressure drop range, hold inclination and azimuth (HIA), and dual downlinking capabilities. As an example, an ABSS may include onboard near-bit sensors that may acquire continuous six-axis inclination and azimuth measurements with a 6-ft range, and optional natural gamma ray and azimuthal images with a 9-ft range. As an example, an ABSS may include one of more features of one or more of the NEOSTEER family of ABSSs (SLB, Houston, Texas).

As an example, a framework may provide for considering information from planning with offset analysis and adapting a hybrid model for real time execution; considering various downhole automation possibilities at a given time to optimize a recommended working trajectory execution, taking advantage of tool capabilities and minimizing unnecessary surface actions; considering real-time data information and derived tool health as well as tool state estimation at a given point in time to optimize current ongoing recommendation and recommend real time correction to handle deviations when it occurs. Such an approach may involve different computations and actions that may output an optimal recommendation, for example, for a fastest path with minimized risk based on the drilling constraints and the drilling context.

As to an optimal path recommendation, derivation may be via a framework, which may provide for a single-target approach and/or a multi-target approach and, for example, which may account for various factors, which may include energy, emissions, etc.

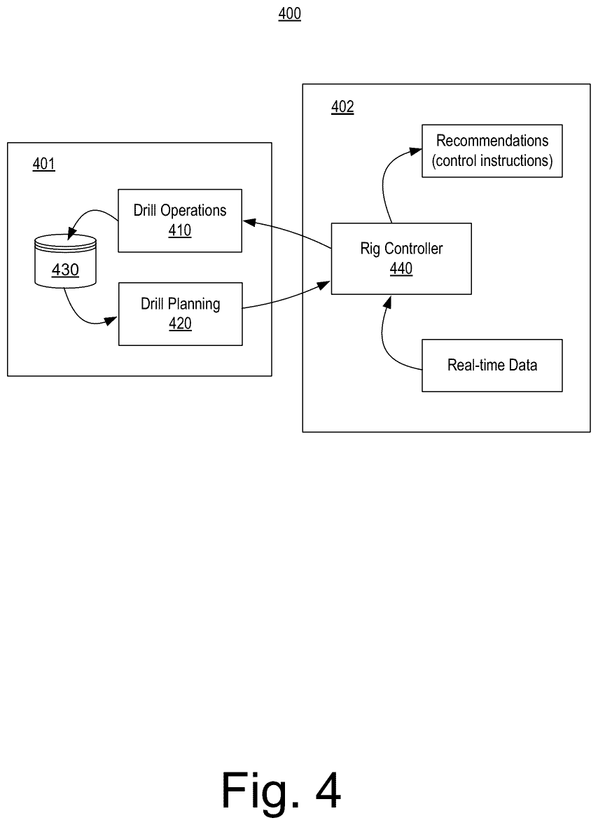

FIG. 4 shows an example of a system 400 that includes offsite equipment 401 (e.g., remote) and onsite equipment 402 (e.g., local). As shown, the offsite equipment 401 may include a drill operations framework 410, a drill planning framework 420 and a database 430 and the onsite equipment 402 may include a controller 440 that may receive real-time data and output recommendations such as control instructions to control onsite equipment. In such an example, the drill operations framework 410 may provide for steering sheets, execution parameters, etc., and the drill planning framework 420 may provide for evaluation of steering responses and statistics. As shown, the controller 440 may output information to the drill operations framework 410 and receive information from the drill planning framework 420. The system 400 may include plan generation features for real-time plan generation during drilling operations execution phase and/or plan generation during a planning phase. The system 400 may be utilized for one or more types of drilling (e.g., rotary, mud motor, RSS, ABSS, etc.). The system 400 may operate loops, which may include at least one real-time loop that provides for control of equipment to perform drilling operations.

A system such as the system 400 may utilize various functions and constraints for generation of plans, which may provide for single or multiple target aiming. Such a system may provide for re-planning, for example, where additional data become available, which may be from a rig site and/or from one or more offset sites (e.g., offset rig or wellsites).

As explained, planning may implement a drill planning framework such as the drill planning framework 420. Such a framework may include components that form a planner. As an example, a planner may utilize one or more types of languages. For example, consider the Planning Domain Definition Language (PDDL) that may be utilized for a specifying planning problem. An article by Fox and Long, entitled “PDDL2.1: An Extension to PDDL for Expressing Temporal Planning Domains”, Journal of Artificial Intelligence Research 20 (2003) 61-124 is incorporated by reference herein. An example of PDDL is given below for a vehicle domain:

```
(define (domain vehicle)
  (:requirements :strips :typing)
  (:types vehicle location fuel-level)
  (:predicates (at ?v - vehicle ?p - location)
    (fuel ?v - vehicle ?f - fuel-level)
    (accessible ?v - vehicle ?p1 ?p2 - location)
    (next ?f1 ?f2 - fuel-level))
(:action drive
  :parameters (?v - vehicle ?from ?to - location
    ?fbefore ?fafter - fuel-level)
  :precondition (and (at ?v ?from)
    (accessible ?v ?from ?to)
    (fuel ?v ?fbefore)
    (next ?fbefore ?fafter))
  :effect (and (not (at ?v ?from))
    (at ?v ?to)
    (not (fuel ?v ?fbefore))
    (fuel ?v ?fafter))
)
)
```

As an example, a plan may include one or more plan metrics. The use of plan metrics may be subtle and may have a dramatic impact on plans being sought. As an example, consider a case where actions increase a metric that is to be minimized, or decrease one that must be maximized. In the foregoing vehicle domain example, a drive action may worsen the value of the plan metric. While this situation might appear to be relatively straightforward, a planner generally attempts to use as few actions to solve a problem as possible. And, in this example, planning is a little more complex than it may appear as there may be rival plans with more actions but lower overall cost. A more complex case may arise when some actions improve the quality metric while others degrade it. For example, if a maximizing metric is used along with an added refuel action to the domain, then driving will degrade plan quality by reducing the fuel level of a vehicle but refueling will improve plan quality by increasing the fuel level of a vehicle. In this case, a planner may attempt to use actions to improve the plan quality without those actions actually contributing to achieving the goals. For example, refueling might not be necessary to get a vehicle to its destination, but adding refueling actions would improve the quality of a solution. This process could involve trading off finite and irreplaceable resources for the increased value of the plan. This would be the case if, for example, refueling a vehicle took fuel from a finite reservoir.

Various planners may account for durative actions, which in the realm of PDDL may include discretized durative actions and continuous durative actions. In such an approach, logical change may be instantaneous, therefore the continuous aspects of a continuous durative action may refer to how numeric values change over an interval of the action. Modelling of temporal relationships in a discretized durative action may be via temporally annotated conditions and effects (e.g., conditions and effects of durative actions may be temporally annotated). Annotation of a condition may make explicit whether the associated proposition is to hold at the start of an interval (the point at which the action is applied), the end of the interval (the point at which the final effects of the action are asserted) or over the interval from the start to the end (invariant over the duration of the action). Of further note in PDDL, when time is introduced into the modeling of a domain it is possible for concurrent activity to occur in a plan. A PDDL approach may be implemented in planning within dynamic and unpredictable environments.

In the realm of drilling and/or other field operations, risk may arise, which may be to some extent unpredictable or poorly estimated. As an example, a drilling framework that includes and/or is operatively coupled to a planner may be improved through risk evaluation. For example, consider generation of a well risk index that relates to a quantitative evaluation of complexity of a well construction process where the well risk index may be utilized by a planner to improve planning and plan execution. As an example, a drilling framework may utilize such an approach to reduce non-productive time (NPT) where, for example, particular field operations are identified quantitatively as to their potential to introduce NPT.

A well planning process entails assessing various types of risk. A well engineer may be an individual with detailed information about a well to be planned. In some instances, the well engineer may report to a more experienced individual, for example, in a hierarchy of a services company. In such an example, the more experienced individual is unlikely to possess the detailed information possessed by the well engineer, noting that time and resources may be lacking for such a transfer of detailed information. For example, the more experienced individual (e.g., a supervisor) may be responsible for reviewing output of more than one well engineer (e.g., ten to one-hundred well engineers).

As to an example of review, consider a well engineer report that relies on details to specify a particular rate of penetration (ROP). In such an example, the ROP may be sufficient and be approved without going into the details. As explained, ROP may be a determining factor in time to drill a section of a well, noting that ROP may vary during drilling due to depth, downhole conditions, surface conditions, equipment conditions, etc. Thus, approving a well engineer's stated ROP may depend on whether or not the overall time for drilling the well or a section thereof appears to be acceptable. However, risks that exist in drilling may be manifold and, where an event actually occurs, there may be a substantial amount of NPT such that the expected overall time for drilling the well or a section thereof cannot be met. In an extreme example as to time, upon occurrence of an event, the amount of actual time for drilling may be more than 1.5 times the expected overall time for drilling (e.g., consider an event introducing 50 hours, 100 hours or more of NPT). Additionally, an event may possibly damage a borehole, which, depending on the extent of the damage, may result in abandoning the borehole or a portion thereof. Hence, in addition to review of metrics such as ROP, a supervisor understands that risks may be a major concern. In general, risks may be more difficult to communicate than a metric such as ROP.

As an example, a computational framework may include features for generation of one or more well risk indexes. A well risk index (WRI) is an indicator that may be generated using data from one or more offset wells, offset from a specified well, by, for example, performing an offset well analysis using the data where a result or results thereof may be related to one or more drilling operations to be performed at the specified well. One or more WRIs may provide for clear communication of risk for one or more activities involved in drilling a well.

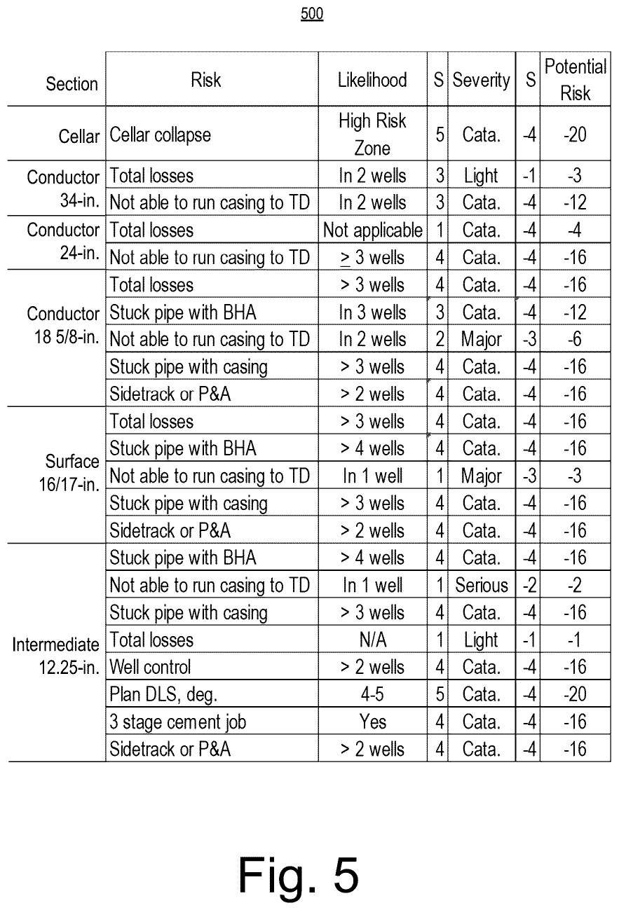

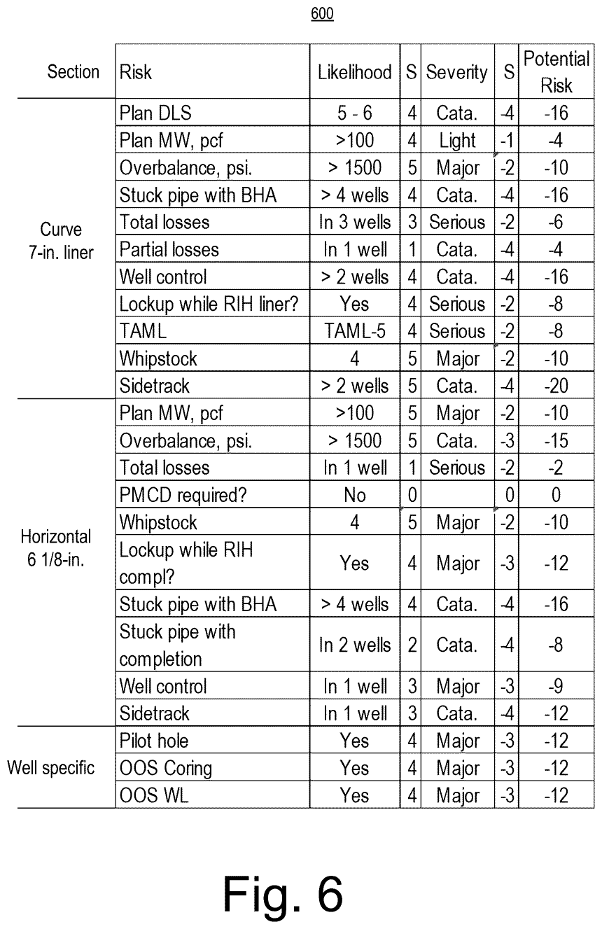

FIG. 5 and FIG. 6 show examples of graphical user interfaces (GUIs) 500 and 600 that include various types of risk information for a specific well to be drilled, further drilled, etc. In particular, a column labeled “Potential Risk” includes values and/or color coding for communication of WRIs. As an example, one or more types of notifications may be specified by the GUI 500 and/or the GUI 600.

As shown in the examples of FIG. 5 and FIG. 6, the GUIs 500 and 600 include a section column that lists various sections that may include: cellar, conductor (larger), conductor (smaller), 18⅝-in, 16-in or 17-in, 12.25-in, 7-in, and 6⅛-in. As indicated in the GUIs 500 and 600, drilling may progress by sections where smaller diameter sections follow larger diameter sections. Further, one or more sections may be vertical while one or more other sections may be curved (e.g., according to a dog-leg severity (DLS)) and while one or more other sections may be horizontal. As explained, drilling may involve directional drilling where a borehole to be drilled deviates from vertical. Directional drilling may introduce various types of risk and/or heighten risks that may exist in vertical drilling (e.g., non-directional drilling). As shown in the GUIs 500 and 600, one or more risks may be specified for each section, along with a likelihood with a score and a severity with a score, along with a WRI (see “Potential Risk”). In such an example, the likelihood, as indicated, may be based on data from one or more offset wells. For example, consider the risk of “stuck pipe with BHA” for the 18⅝-in section as having a likelihood of “3 wells” with a score of 3 and the risk of “stuck pipe with BHA” for the 12.25-in section as having a likelihood of “≥4 wells” with a score of 4. For these two examples, severity may be catastrophic with a score of 4. As to “Potential Risk” (e.g., WRI), for these two examples indexes may be “−12” and “−16”, respectively, both of which may be color coded in red. In contrast, consider the risk “not able to run casing to TD” for the 12.25-in section as having an index of −2 and a color code of green. As an example, various entries may be color coded (e.g., consider yellow, blue, black, etc.).

As explained, the GUIs 500 and 600 may communicate risk effectively, particularly in the column “Potential Risk” using a series of WRIs. The GUIs 500 and 600 may be generated using a computational framework driven by a well engineer where the framework may access appropriate offset well data along with information about a specific well for which drilling operations are planned. In a hierarchical organization, a supervisor may readily review the planned sections and associated potential risk, which may provide an indication as to risks of not meeting one or more goals (e.g., drilling a viable borehole within an estimated time).

As an example, the GUIs 500 and 600 may be rendered as part of a planning workflow. For example, where one or more WRIs are deemed to be too high, a planning framework may reassess one or more planned drilling operations in an effort to reduce one or more of the WRIs. Thus, one or more WRIs may be utilized as feedback in a planning process implemented by a planning framework.

As an example, a WRI framework may be integrated into or otherwise accessible by a planning framework (e.g., DRILLPLAN framework). And, for example, where a digital well plan is being executed and one or more conditions arise that call for re-planning, the WRI framework may be implemented in the re-planning. For example, if conditions indicate that stuck pipe is more likely than originally expected, then a stuck pipe risk likelihood may be increased above that determined via an offset well analysis. As another example, if an event occurs but its severity is less than that resulting from an offset well analysis, the severity may be adjusted (e.g., for a section that experienced the event and/or for one or more following sections). In such an approach, a WRI framework may be dynamic and facilitate planning and re-planning, the latter of which may be triggered by one or more conditions associated with actual drilling operations for a specified well. In various instances, a specified well may be an offset well to another specified well. In such instances, one or more likelihoods may be updated responsive to occurrence of an event (e.g., a stated risk). For example, if stuck pipe occurs in a first well, that event may be automatically communicated to a WRI framework that utilized that first well as an offset well for a second well. As an example, where one or more WRIs change dynamically to increase potential risk beyond that specified in an original WRI report (e.g., GUI), that may act as a trigger for re-planning one or more sections of a well.

As explained, one or more WRIs may be integrated or otherwise provided to a planning framework (e.g., via an application programming interface (API), etc.). As an example, a workflow may depend on an offset well analysis and simulations performed for a specific well (e.g., drilling simulation, flow simulation, completions simulation, stimulation simulation, etc.). As an example, a drilling framework may utilize one or more types of graphics to communicate risk. For example, consider a stick chart that presents major risks identified from offset wells, along with severity of the risks. As an example, risks currently identified via WRIs may be picked from a stick chart (e.g., stuck pipe, well control in offset wells, etc.), from simulations (e.g., value of dogleg severity, buckling while drilling and/or tripping, etc.), etc. In such an approach, a planning framework may provide output for a risk framework that may generate WRIs. As an example, risks generated by a planning framework may be converted into an appropriate format for purposes of WRI generation, for example, such that they may be used to identify risks with highest likelihood and severity, and, for example, to develop the preventative and mitigation measures.

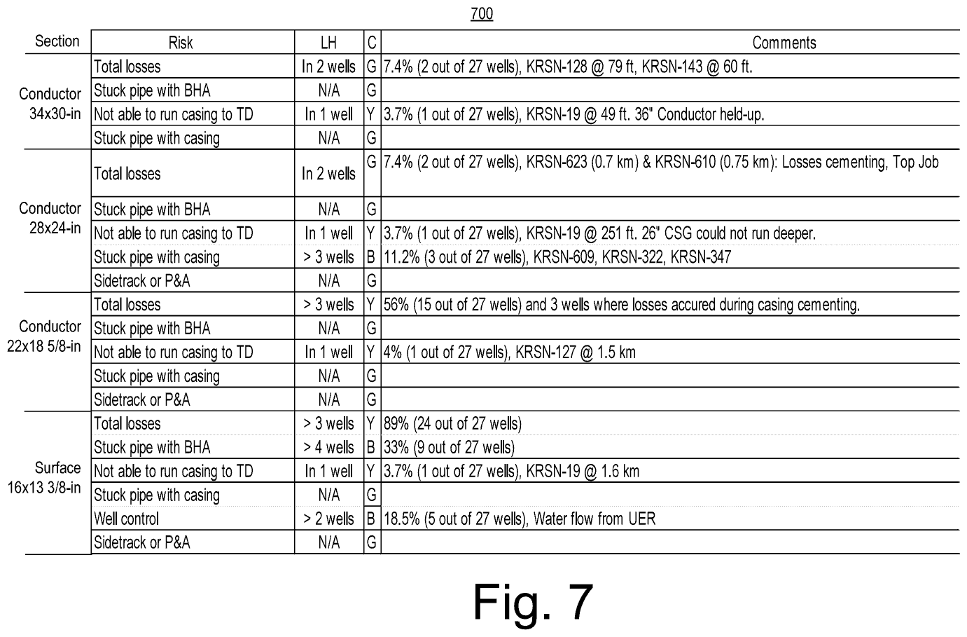

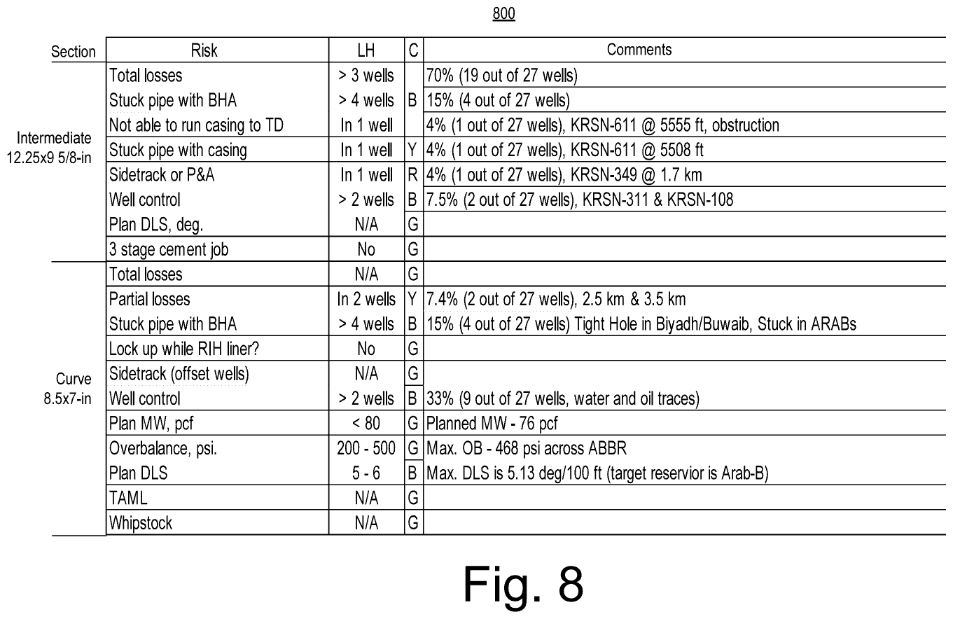

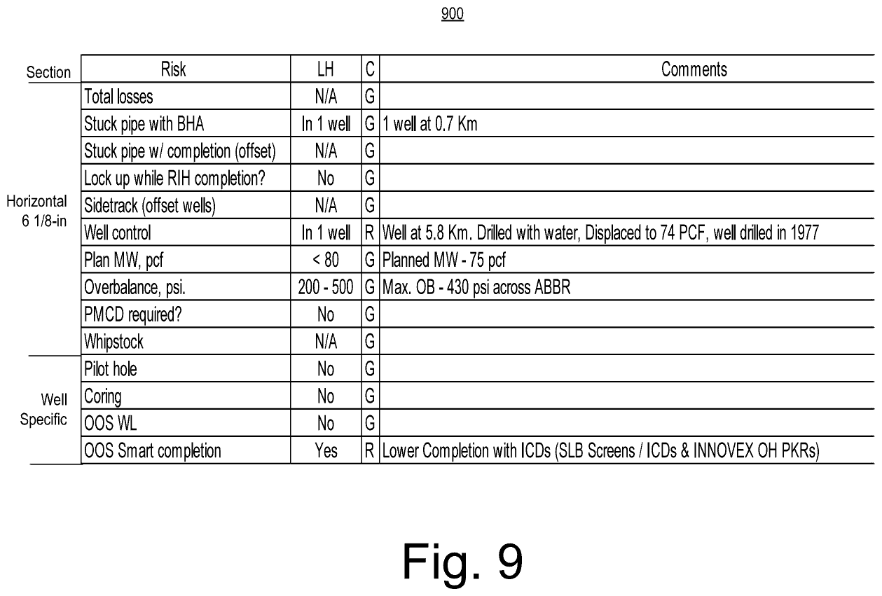

FIG. 7, FIG. 8, and FIG. 9 show examples of GUIs 700, 800, and 900 that include various types of information as in the GUIs 500 and 600. In the example GUIs 700, 800, and 900, the WRIs may be indicated through use of color coding, noting that one or more types of coding schemes may be utilized (e.g., color, shading, hatching, etc.). As shown in a column labeled C for colors, colors are indicated by codes G for green, Y for yellow, B for black, and R for red.

As shown, the GUIs 700, 800, and 900 may include one or more comments, which may provide additional insights. For example, consider generation of comments using offset well data and associated comments. In such an example, a natural language processing (NLP) engine may be utilized for extracting and homogenizing comments or otherwise organizing, synthesizing, etc., comments with respect to one or more offset wells.

Some examples of computations that may be performed by a framework are given below.

Example for risk of cellar collapse:
Formula #1. Estimation of the potential likelihood. IF 1 well within 1 km radius, then “High Risk Zone”; or IF 1 well within 2.5 km radium, then “Medium Risk zone”; or IF no well within 2.5 km, then “Low risk zone”.
Formula #2. Estimation of the likelihood score. IF potential likelihood=“Low risk Zone” then score 2; IF potential likelihood=“Medium Risk Zone” then score 4, otherwise score 5.
Formula #3. Estimation of the potential Severity. IF potential likelihood=“Low Risk Zone” then “Light”; IF potential likelihood=“Medium Risk Zone” then “Major”, IF potential likelihood=“High Risk Zone” then “Catastrophic”.
Formula #4. Estimation of potential severity score. If Potential severity “Light” then “−1”, IF Potential severity “Serious” then “−2”, IF Potential severity “Major” then “−3”, Potential severity “Catastrophic” then “−4”,
Formula #4: Estimation of Potential Risk. Multiplication of potential likelihood and potential severity. If final value “−1”, then color code “green”; IF final value “−4”, then color code “red”; final value “−20”, then color code “black”.

While various examples pertain to drilling of wells, a framework may be tailored for one or more other types of domains. For example, consider mining, construction, marine, etc.

As explained, a framework may provide for estimation of hazards at a well planning stage, for example, by bringing identified risks to the attention of one or more decision makers and, as a result, allocate one or more additional preventative measures, resources, equipment aiming to decrease residual likelihood and/or severity, etc. Such an approach may help to reduce potential non-productive time during well construction, for example, for faster well delivery and avoidance of expensive remediation activities.

As an example, a framework may provide for a relatively straightforward output of risk, which may be a single page or a couple of pages. In comparison, a well engineer report may be over 100 pages in length, which may be time consuming to review even by a more experienced individual. As access to more experienced individuals may be limited in time, expediting review of risk may improve drilling workflows. As an example, a more experienced individual may be provided output for risk to evaluate potential risks and to propose one or more prevention actions. As an example, a reviewer may provide feedback that may be utilized in a re-planning process.

As explained, well construction involves various actions, which may include a series of actions that may be repetitive from one well to another. Under such conditions, an assumption may be made that drilling operations for the same well type on the same field or type of field may have similarities (e.g., risks, performance, etc.). However, in reality there may be differences related either to a part of the field, or type of the equipment used, or the drilling practices used as may be accomplished by a knowledge sharing process. The effect of such factors may be directly proportional to scope of work (e.g., the number of rigs, etc.).

As explained, a starting point for a well may be for a planning stage, where offset well information may be gathered for use in planning a well in a most convenient manner, for example, based at least in part on best practices from the field. At the same time, such best practices may be subjected to filtering via a risk management process to define the final strategy. At this stage, a balance between the expected NPT, risk and the performance may be identified and agreed upon.

As an example, consider an operation such as a wiper trip. A wiper trip may be an abbreviated recovery and replacement process of a drillstring in a wellbore that usually includes a bit and BHA passing by an openhole section, or at least a portion of an openhole section that may be suspected to be potentially troublesome. A wiper trip may vary from a short trip or a round trip in its function and length. One or more wiper trips may be utilized used when a particular zone is troublesome or if hole-cleaning efficiency is questionable.

As an example, consider a wiper trip tripping a BHA out of an openhole from a current well total depth (TD) and running it back into the openhole either to the current TD or another specific depth prior to performing a final pull out of hole or resuming drilling. One goal of a wiper trip may be to ensure that consecutive operations, such as run in hole of casing string, logging etc., may be performed in a safe manner without stuck pipe. When a wiper trip is considered to be a productive time, it may be considered as well as a “missed opportunity”. The introduced term “missed opportunity” may be defined as a specific activity during a well construction process which may be either not performed under different circumstances or performed in a more efficient way by using one or more alternative tools, equipment, products. A wiper trip prior to an activity may be skipped, but a proper analysis of historical data, conditions of the wellbore, properties of the drilling fluid may be analyzed and agreed to in advance to make such decision. Often historical data are informative, particularly when substantial tight spots seen during an original POOH are not seen during a wiper trip. However, skipping a wiper trip may lead to quite severe service quality events (e.g., stuck pipe). Hence, as explained, a balance between risk and performance may be assessed and, as appropriate, agreed upon by stakeholders at planning stage. With single rig operation and expected well construction time over 2-3 months, agreement may be achieved via a series of detailed reviews of planned activities and risks, but in the case of a substantial scope of work (e.g., 10 or more drilling or workover rigs with expected well delivery below 30 days) this approach may not work or result in suboptimal planning and/or execution.

As in the example GUIs 500, 600, 700, 800, and 900, well construction activities may be segregated for individual well sections and may utilize categories based on likelihood to have a specific service quality incident (SQI) with potential non-productive time over a specified number of hours. For example, consider a specified time of 48 hours, which may be changed to another value (e.g., depending on local requirements, etc.). An example of high likelihood of potential SQI may be drilling though potentially unstable formation or through a high pressure pay zone that is prone to stuck pipe or well control events. The consequence of such an event is high non-productive time (NPT) as well as reputational damage. An example of a low likelihood of potential SQI may be a cement job of surface casing or run of upper completion, which are not normally not prone to SQI and a substantial amount of NPT.

As an example, a framework may include identifying for a project (e.g., a field, a well, etc.) particular activities that may demand special attention to reduce risk of SQI. In such an example, for different projects, these activities may differ; however, stuck pipe and well control tend to remain the same for most of the projects around the world. Other activities which may demand special attention and evaluation are partial or complete losses, well control events, ability to run a liner or a completion string in a deviated well (e.g., specifically in an extended reach application), wireline or coring jobs etc.

As an example, a framework may identify activities prone to NPT (e.g., according to one or more criteria) and then quantify and qualify the likelihood and severity of events. In such an example, likelihood may be based on an offset well analysis and optionally data from a specified well that may have already had a portion drilled. As an example, well analysis may be implemented in an online manner where well data may be acquired in real-time or near real-time from one or more wells, databases, etc.

As an example, a framework may implement one or more types of filters, which may be adjustable automatically and/or through interaction using a GUI, etc. For example, consider a radius or other boundary type of filter (e.g., offset wells within 3 km), year of an event in an offset well, well type, etc., depth, formation type, fluid type, etc. As an example, a framework may determine severity, which may be from reports, comments, etc., as to one or more offset wells that may include information for identifying recovery time and/or estimating recovery time from a potential incident. For example, if a particular offset well took X hours to recover from an event, then that time may be utilized to estimate a recovery time for a specified well. Such information may be utilized, for example, in assess NPT in association with one or more types of events.

As an example, a framework may determine a specific value for likelihood and a specific value for severity (e.g., prior to implementation of one or more prevention measures). As explained, a framework may determine a potential risk of a specific activity, which may be determined by a product of a likelihood value and a severity value. For example, consider a likelihood value of 3 and a severity value of 2, which may be multiplied to arrive at a potential risk of 6.

As an example, a framework may provide for color coding of potential risk. For example, consider a color-coding scheme with five different levels: insignificant and low (green color), medium (yellow color), high (red color) and extreme (black color). Based on the estimate potential risk, a GUI may be rendered that may draw attention to different levels within a drilling organization. For example, the “very light” and “light” potential risks may remain with a well engineer; whereas, the serious, higher levels of potential risk may be brought to an engineering team leader, and major and catastrophic levels may be reviewed by engineering and/or operations managers, which may provide for review and approval of a dedicated prevention and mitigation plan. In such an approach, potential risk as output by a framework may help to assure that risk is properly communicated and reviewed within a hierarchy of individuals. For example, consider the GUIs 500 and 600 of FIG. 5 and FIG. 6 as providing for appropriate review where color coding may be utilized to assure proper review within a hierarchy.

In various instances, when having a likelihood of an undesired event is quite a straightforward process, then evaluation of potential severity may be more complicated. For example, the same event in different offset wells may have led to different results, which may be based on particular practices, reactions of crew, etc. Such specific information may be challenging to quantify. As an example, a framework may implement one or more approaches to quantify information. For example, consider one or more of analyzing available offset data to have a comprehensive and qualitative understanding of the severity (see, e.g., the GUIs 500 and 600), sticking to the most severe event in terms of NPT and considering it to be a reference point, and foregoing a severity part and basing on analysis on likelihood (see, e.g., the GUIs 700, 800, and 900). Of the three foregoing examples, the second and the third may be suitable in instances where there is limited information and/or resources as accurate estimation of severity may be time consuming (e.g., which may eventually bring the same result).

As explained, a WRI may be utilized for one or more purposes. For example, a WRI may be utilized in planning and/or execution to help reduce risk of occurrence of an undesirable service quality event and a WRI may be utilized to highlight an expected risk and level thereof, which may, in turn, be used to trigger one or more prevention and mitigation measures, such as, for example, one or more of critical activity risk evaluation (CARE), change of standard plan, use of extra tools (as casing while drilling), readiness of remedial tool and equipment, etc. As explained, a WRI approach may be readily segregated or classified in a manner that may align with objectives at different levels of an organization, without having to go into details for each well.

As an example, a framework may be implemented during and/or after a well planning stage for a specified well. For example, during a well planning stage, after the preliminary information about the planned well is gathered, (e.g., offset well analysis, trajectory, formation pressure, mud weight, etc.), a well engineer in charge may utilize a framework to generate a WRI matrix, which may be rendered as a GUI. In such an example, the WRI matrix may be distributed for review, optionally a joint review where individuals simultaneous view the GUI. Such individuals may include various stakeholders, including individuals such as one or more of a senior well engineer, a drilling superintendent, an OI (quality) manager, an engineering manager, an operations manager, a drilling fluid engineer, and a project manager. During a WRI review, medium, high and extreme risks may be analyzed, and proper preventative and mitigation actions agreed upon. A WRI review may result in feedback, which may be received via a GUI and utilized in planning, for example, by a planning framework to revise a plan.

For an activity where interaction with a customer may decrease risk (e.g., change of target entry, use of casing while drilling, review of mud weight, etc.), communication may be established with the customer with specific requests. In the case where an integrated well construction (IWC) engineer is not capable to solve it on her own, proper escalation may occur.

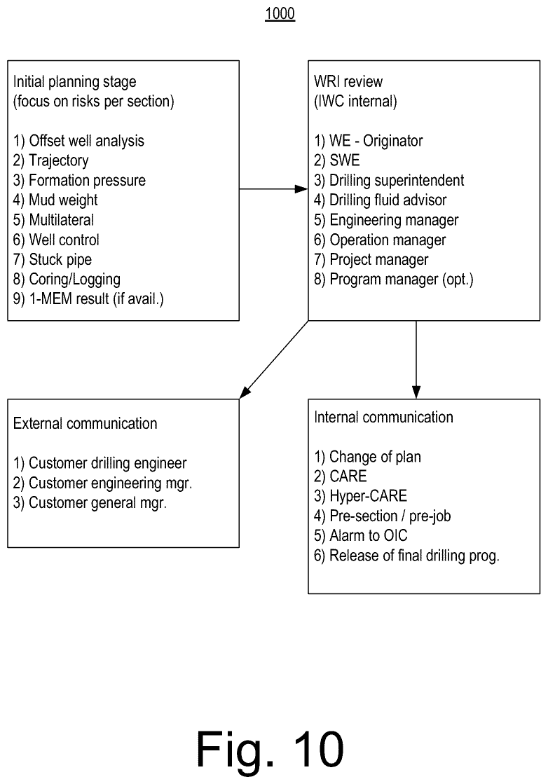

FIG. 10 shows an example of a workflow that includes various blocks, including an initial planning stage block that may focus on risks per section, a WRI review block that may be generated under guidance of a IWC process, an internal communications block and an external communications block. As shown, the initial planning stage block may provide various types of data using one or more of offset well analysis, trajectory, formation pressure, mud weight, multilateral(s), well control, stuck pipe, coring/logging, mechanical earth modeling (MEM), etc. As explained, risks may be determined on a section-by-section basis.

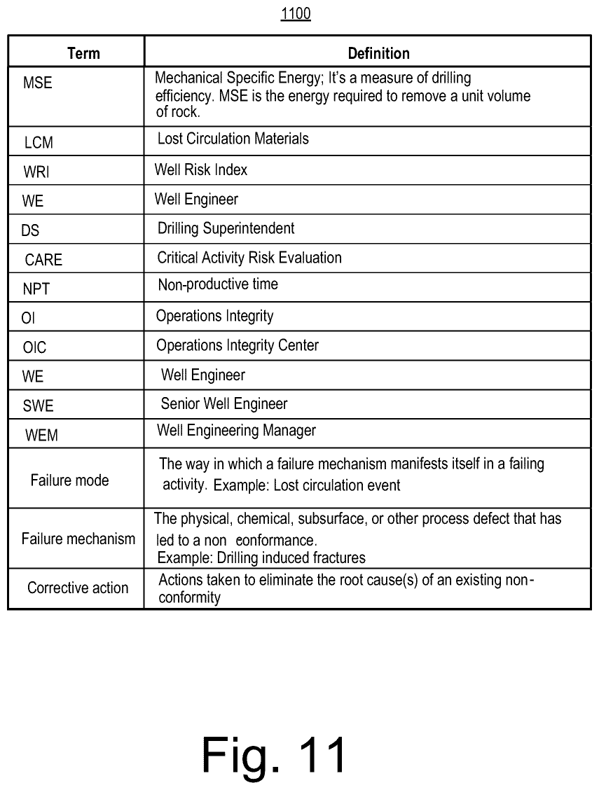

FIG. 11 shows an example of a table 1100 that may be rendered as a GUI to a display. The table 1100 provides various acronyms together with definitions. As an example, a WRI framework may utilize a particular language corpus, which may be adjustable to adapt to one or more types of service entities, types of fields, etc. As an example, one or more tables, etc., may be utilized for purposes of building, augmenting, utilizing, etc., a knowledge system that may be an ontology-based knowledge system.

As an example, a framework may provide for implementation of an ontology-led approach that learns from root-cause analysis. For example, consider a framework that may leverage one or more knowledge systems which may learn from root-cause analysis, which may provide for assessments as to immediate causes, root causes, etc.

As an example, a knowledge-system may learn from root-cause analysis. In such an example, a framework may implement an ontology of a well construction process that may include taxonomies of well construction such as, for example, activity codes, failure types, WITSML descriptions of a BHA, fluids, etc. Such taxonomies may be linked using sematic web constructs such that one or more machine inference engines may infer connections between items that may not necessarily be explicit in an initial representation.

As an example, a framework may provide for rendering of one or more GUIs where a user may be presented with relevant information from a particular wellsite operation. This information may be retrieved via query from an ontology and may include relevant information from one or more offset wells from the same field and wells that may be inferred to be similar (e.g., via one or more similarity measures). In such an approach, a portfolio of cases may be used on reviewing a particular wellsite operation.

As an example, upon analyzing a current case, in the context of a portfolio of cases, a root-cause analysis, best-practice, lessons-learned, etc., may captured via a guided description system. As an example, a guided description system may aid a user in capturing user expertise in a form that may be consumable by an ontology.

As an example, captured information may be retrievable via query, for example, when a new wellsite operation is planned, a search based on one or more similarity measures may be implemented to recover relevant lessons learned, which may be presented to include corresponding links back to a root-cause analysis or analyses that may have generated the lessons learned.

As an example, a framework may provide for automation in assessments for field operations. For example, consider a dynamic interface (e.g., GUI) where an individual in the field may enter notes such as comments regarding conditions, field operations, etc. In such an example, consider driller notes for drilling operations. Upon entry of such notes, a framework may utilize an ontology-based approach that guides user note entry, editing, etc. For example, consider a framework that helps guide an individual in constructing entries according to one or more rules such that states may be extracted. In such an example, consider utilization of constructs such as prepositions, prepositional modifiers, prepositional complements, adjectival complements, open clausal complements, objects, etc. Such an approach may guide an individual in entry of comments in appropriate forms such that states may be extracted.

As an example, consider a driller entering text such as “going on bottom, turning at X rpm, flowing at Y gpm”. In such an example, a framework may understand through use of an ontology that going on bottom relates to engaging a drill bit with a bottom of a borehole to continue drilling. Such a framework may also understand that three actions are involved through identification of three distinct gerunds (e.g., going, turning, and flowing). The framework may automatically rephrase the comment into three separate actions such as, for example: lowering drill bit to engage bottom of the borehole; rotating drillstring at X rpm; and flowing drilling fluid at Y gpm. Where the individual approves these rephrased entries (e.g., or otherwise edits as appropriate), the framework may extract states that may be meaningful to a machine (e.g., a computational framework). For example, consider extracted states: (drill bit, lower, bottom_of_hole); (drillstring, rotate, X_rpm); and (mud, flow, Y_gpm).

As explained, a framework may provide for guided state extraction where extracted states may be utilized for interaction with a knowledge system. In the foregoing example, three extracted states may be deemed to exist at a particular time and, for example, at a particular depth in a borehole in a subsurface region. Hence, data (e.g., metadata, time, place, depth, etc.), may be acquired and utilized for interaction with a knowledge system. In such an approach, the knowledge system may be queried (e.g., using a prompt, etc.), to return information regarding the driller's indicated activities at that particular time under the circumstances, which may include consideration of prior activities performed at the site and/or planned activities to be performed at the site. As an example, a knowledge system may return a statement such as “acceptable risk, continue” or, for example, “decrease drillstring rpm to X1 rpm and increase mud flow rate to Y1 gpm to reduce risk of unacceptable shock”. In such an approach, the feedback may be actionable at the discretion of the driller.

As an example, a framework may capture a driller's action or actions via entries to a GUI, automatically via GUI interactions, via sensor-based data, etc. For example, in the foregoing example, a framework may understand automatically whether or not one or more of the recommendations were implemented. In such an example, the framework may generate additional output such as, for example: “drillstring rpm decreased to X1 rpm but mud flow rate increased to only Y2 gpm, please monitor shock and vibration data”.

As another example of an entry by an individual and/or from one or more documents stored in a database, consider a statement such as “cuttings were sinking”. Such a statement, to a driller or other experienced individual, would be understood to describe a condition where cuttings from a drill bit of a drillstring breaking rock at a bottom of a borehole to lengthen the borehole are not being adequately lifted to surface in an annulus between the drillstring and a borewall (e.g., cased and/or open) by the flow of drilling fluid. Such a condition may be due to one or more factors, which may include mud weight (e.g., drilling fluid density). Such a condition may be related generally to a process referred to as hole cleaning, which pertains to an ability of a drilling fluid to transport and suspend drilled cuttings. Factors in hole cleaning may include annular-fluid velocity, hole inclination angle, drillstring rotation, hole/pipe eccentricity, rate of penetration, mud properties, cuttings characteristics, etc. Inadequate hole cleaning may lead to one or more issues, which may include, for example, one or more of mechanical pipe sticking, premature bit wear, slow drilling (e.g., low ROP), formation fracturing, excessive torque and drag on drillstring, difficulties in logging and cementing, difficulties in casings landing, etc. Hole cleaning may be controlled, for example, by control of one or more of annular velocities, drilling-fluid viscosity, pipe-rotation speed, and pipe eccentricity. Hence, where a statement indicates “cuttings were sinking”, various factors and/or physical phenomena may be involved. As an example, a framework may provide for characterizing such a statement using one or more techniques, which may include one or more of guided authoring techniques and state extraction-related techniques. In such an example, the framework may aim to fill in a gap that may not be explicit and/or may not necessarily be able to be understood by a machine. As an example, a framework may augment and/or structure a statement such that a data structure may be generated that may be sufficient for consumption by a machine. In such an example, the data structure may be for purposes of utilization with or within a knowledge system, an ontology, a controller, a simulator, etc. As explained, while a human may understand what a statement means, the statement itself may be insufficient for purposes of generation of and/or utilization of a knowledge system. Hence, a framework may provide for enriching a statement such that an appropriate data structure may be generated and utilized for one or more purposes.

As an example, a framework may provide for generation of recommendations, suggestions, etc., which may involve generation of remedial actions, preventive actions, etc. As an example, a framework may provide for, responsive to receipt of a statement, generation of an action such as modifying a drilling fluid to address hole cleaning where the modifying may include mixing an additive into the drilling fluid to adjust mud weight (e.g., drilling fluid density). In such an approach, the framework may have access to additives available at a site and/or may recommend use of an additive that may be likely procured within a period of time to meet an objective of a field operation without excessive delay (e.g., NPT, etc.). While such an example pertains to a hole cleaning scenario, additives may be recommended to address one or more other types of scenarios such as, for example, lost circulation where an additive may be a lost circulation material (LCM) that aims to stem loss of drilling fluid.

As explained, knowledge within a knowledge system may be based at least in part on historical data generated from field operations at a site and/or field operations at one or more offset sites. As explained, a framework may be implemented with respect to a process of offset well analysis (OWA) to capture knowledge to improve a knowledge system.

As explained, a framework may provide for guiding user input to more effectively generate output. In such an approach, the framework may help to generate data that may be utilized to improve a knowledge system in terms of effectiveness, scope of knowledge, etc.

As an example, a framework may provide for problem solving such as, for example, root cause analysis. For example, if a driller enters “drillstring sticking”, a framework may respond with or without rephrasing to a GUI depending on urgency and not distracting a driller's focus as the driller may be keenly focused on sticking of the drillstring. In such an example, the framework may extract a state, interact with a knowledge system, and return one or more recommendations to address the sticking issue. In such an example, the framework may return a likely immediate cause and/or a likely root cause as to the sticking issue. For example, consider one type of cause as being inadequate hole cleaning such that sticking may be a result of a buildup of cuttings in a portion of a borehole.

An article by Janghorbani et al., Domain Authoring Assistant for Intelligent Virtual Agent, AAMAS '19: Proceedings of the 18th International Conference on Autonomous Agents and MultiAgent Systems, May 2019, Pages 104-112 (doi/10.5555/3306127.3331680), is incorporated by reference herein in its entirety. As an example, one or more techniques and/or technologies described in the article by Janghorbani et al., may be implemented by a framework that may provide for guided entry and/or knowledge system tasks.

As an example, a framework may be implemented in a real-time manner during field operations, in a pre-field operations manner (e.g., planning, etc.), in a post-field operations manner (e.g., forensics, future operations, etc.), etc. As an example, a framework may be operable for use with human-based and/or machine-based information. For example, a framework may be utilized for automated planning and/or control. As an example, a framework may provide for receipt of entries that may be natural language entries of a human and/or that may be machine language entries of a machine. In such an approach, a framework may be a hybrid NLP and machine language processing framework. As an example, consider automated control of a drilling operation where a framework may generate natural language output for presentation to a user via a GUI, for use in a database (e.g., a knowledge system database), etc., for purposes of monitoring, improvement of a knowledge system, etc.

As an example, a framework may provide for automation to supplant manual processes as to lessons learnt from root-cause analysis as may be common in one or more other types of frameworks. Such automation may reduce demand for manual updating of wellsite checklists for future similar operations, which may be a tedious and subjective manual process lacking contextual review, for example, which may lead to checklists getting ever longer. As an example, a framework may provide for more timely, consistent and objective output (e.g., and/or input). As an example, a framework may operate in a manner that may be relatively user expertise agnostic in that finding and applying lessons learnt leads to results that do not vary depending on expertise of a user.

As an example, one or more techniques, technologies, etc., of a platform such as the TOPBRAID platform (TopQuadrant, Inc., Raleigh, North Carolina) may be utilized by a framework and/or a knowledge system. The TOPBRAID platform provides a family of integrated tools developed, including a composer, an RDF schema and OWL ontology editor, and a semantic web application server.

As an example, a framework may provide for investigation practices and workflows in a drilling domain, that may involve structuring and contextualization of knowledge extracted from one or more investigations.

As an example, as field operations and/or events (e.g., related to risks, etc.) occur during a drilling process new knowledge may be generated, which may include knowledge generated after structured investigations take place. Such a process may lead to best practices, what to do, and lessons learned, what not to do, etc. As explained, knowledge that is not structured may be problematic or otherwise challenging to utilize. As explained, a framework may provide for structuring, which may be applied to existing unstructured information and/or dynamically upon entry of information (e.g., via one or more GUIs). In such an approach, a knowledge system may provide for improved utilization, gaining of knowledge, etc. As explained, a framework that may include and/or be operatively coupled to a knowledge system may provide for uses that may include access to relevant knowledge during operations stages and/or planning stages. As explained, a framework may provide for automation such that demand for manual activities are reduced and/or facilitated (e.g., take less time with more beneficial use of time).

As to a workflow that may involve investigations, consider, as an example, a scenario where during an investigation process, a team of subject matter experts looks into a root cause analysis that has led to an event, which may be environmental, technical, human, procedural, etc. In such an example, once the root cause has been determined, the team may issue a set of remedial actions that may include alerts or lessons learned. In such an example, these results may be stored in a knowledge management database and, for example, if an event is relevant enough, it may be shared using a distribution list to a larger number of people, entities, etc.

As explained, a framework may operate to help assure that knowledge is captured in a structured manner. In such an approach, a framework may provide for processing of various types of inputs, which may be a combination of types (e.g., consider text and pictures, etc.). In such an approach, the framework may provide for making workflows more efficient, for example, by facilitating searches of knowledge as captured in a knowledge system. As to the team-based approach, a framework may operate to help assure that a systematic distribution of knowledge may be performed in a reliant manner, for example, to help assure that awareness of various events is maintained; rather than a substantial fraction of specific knowledge remaining solely within the team that witnesses the event or participated in the investigation.

As explained, a framework may include various components that may provide for implementation of one or more automated recommendations engines. As explained, a framework may generate recommendations based on historical knowledge as to one or more sites, which may be offset from a site of interest, and/or based on knowledge at a site of interest. As an example, a framework may bring relevant knowledge such as best practices and/or lessons learned to a drilling engineer who is planning a well or drilling a specific section of a well. As an example, a framework may provide for searching through specific attributes that relate planning of a well, operating a well, drilling a well, etc., via a knowledge databank that has knowledge of previous events with similar attributes.

As an example, a framework may implement an efficient approach to assign specific attributes that defined an event to help ensure that such attributes are captured in a structured manned so they may be automatically queried in the future.

As explained, one or more semantic web ontologies may be utilized to contextualize knowledge captured during operations, planning, etc. In such an approach, a framework may provide for extracting knowledge from one or more established event investigation processes (e.g., using one or more adapter, application programming interfaces (APIs), etc.).

As an example, one or more semantic web ontologies may provide for mapping various attributes that define an event. In such an example, to define the event, a web ontology may map a large number of attributes (e.g., more than would be practical for an investigation team to input manually). As an example, a framework may leverage one or more standard protocols (e.g., WITSML protocol) with respect to data structures. In such an example, the framework may provide for processing data stored and/or otherwise available via one or more standard protocols such that attributes, states, etc., may be readily extracted and utilized by a knowledge system. For example, consider a framework that includes features that allow for using data from one or more sources to populate a web ontology automatically. In such an example, an investigation team may be able to readily contextualize knowledge captured after an event in a structured manner with a minimal effort.

As an example, an event that has been contextualized through a web ontology by using a WITSML protocol to populate various attributes may therefore be an event that may be readily accessed by a human through advanced filtering and/or accessed by a suggestion engine according to specific planning or operational requirements.

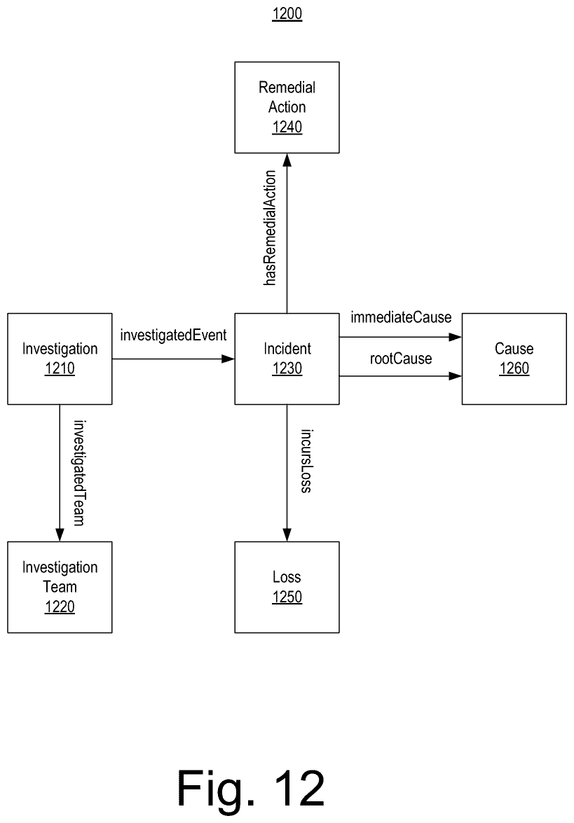

FIG. 12 shows an example of a system 1200 that includes an investigation block 1210, an investigation team block 1220, an incident block 1230, a remedial action block 1240, a loss block 1250 and a cause block 1260. Such a system may be implemented using a framework that may provide for generation of one or more GUIs where, for example, the framework may include and/or be operatively coupled to one or more knowledge systems.

In the example of FIG. 12, a target ontology may be utilized to represent an investigation. For example, an investigation may be represented as a graph where a central object is the Incident that occurred, as represented by the incident block 1230.

This incident object or incident block 1230 may be connected to losses, per the loss block 1250 (e.g., resources, financial, health and safety, etc.). As an example, an investigation per the investigation block 1210 may help to determine a cause per the cause block 1260, which may include one or more causes (e.g., immediate cause and root causes) of the incident of the incident block 1230. In terms of data structures, these causes may be linked to an incident object where, for example, one or more remedial actions may also be linked to the incident object.

As an example, causes themselves may be categorized into various sub-classes while still relating to a state of a system in some manner. As an example, consider predicate causes as stand-alone statements about a system, such as, for example, “lightning strike” or “civil unrest”. Further consider relational causes that these represent relations between system properties or constants, for example, “mud weight exceeded the upper bound of the mud weight window”. Such cause subclasses may be represented precisely in an ontology, for example, as system properties and system states that are codified for this to be the case.

While two subclasses are mentioned, consider one or more additional subclasses, which may include causes that may be represented as either semi-structured or unstructured sentences. For example, semi-structured sentences may include statements such as “a contractor observed that the weather forecast predicted lightning strikes” where lightning strikes are part of a codified system state, but the overall meaning of the sentence may not be represented with respect to the codified system state and system properties. As an example, an unstructured sentence may include any statement with no reference to one or more codified properties.

As explained, a framework may utilize an ontology-led system for root cause analysis. In such an example, an ontology may relate to a well construction process, which may pertain to planning, field operations, etc. As an example, similarity measures may be defined on an ontology that help to recover a portfolio of examples similar to a current example. In such an approach, a framework may operate in a dynamic mode where, responsive to input, the framework may generate output automatically. As explained, a framework may be integrated with a drilling report GUI such that knowledge may be captured and knowledge shared, which may improve drilling at a site and/or drilling at one or more other sites.

As explained, a framework may include a guided description system that may assist users to capture information, which may be notes, comments, control instructions, etc., and which may include results of one or more analyses. As explained, a framework may provide for link generation where, for example, one or more links may be rendered to a GUI where actuation of a link may provide for accessing information as may be associated with an investigation, one or more sources of data, etc., which may be appropriately taken into account within an ontology. For example, if a recommendation is to increase drillstring rpm for a scenario, a framework may render such a recommendation with a graphic with an embedded link, etc., such that a user may actuate the link to cause rendering of information associated with a basis for the recommendation. For example, consider a map rendered to a GUI where a site may be highlighted, which may be an offset wellsite where an incident occurred for which one or more lessens were learnt. In such an example, a user may actuate a graphical control associated with the offset wellsite on the map to cause a framework to retrieve information as to that incident, which may, for example, allow the user to understand more fully context, causes, remedial action, post-incident actions and/or conditions, etc. In such an example, the framework may provide information as to quality of a well at that site and/or details as to completions, etc., which may have been impacted by the incident.

As explained, a framework may provide for capture of knowledge derived from a root cause analysis in a structured manner leveraging an ontology-based system. Such a framework may provide for enriching a knowledge system, generating results using a knowledge system, etc. As explained, results generated may be responsive to input from a human and/or a machine. As explained, a framework may include one or more natural language processing abilities to transform inputs and/or outputs, whether from a human and/or a machine and/or to a human and/or a machine. As an example, a framework may provide for improving automation of field operations at a site, for example, by automatically responding to one or more conditions where output may be generated that may be rendered to a GUI for ready understanding by a human and, as appropriate, human intervention. As an example, an automated system for performing one or more field operations may be operable at one or more levels of automation where, for example, a level may be adjusted to call for more or less human intervention (e.g., human-in-the-loop (HITL) intervention). As an example, such an approach may be implemented in an automated manner, for example, where a result from a framework indicates that a risk of an event occurring is high (e.g., above a threshold), the framework may automatically instruct an automated system to decrease its current level of automation such that a human may take over at least some aspect of control of a field operation. By providing such assurances, automation may be implemented with a higher level of confidence as a system may know when conditions present challenges (e.g., risks of events) that may be beyond the capabilities of automated control system.

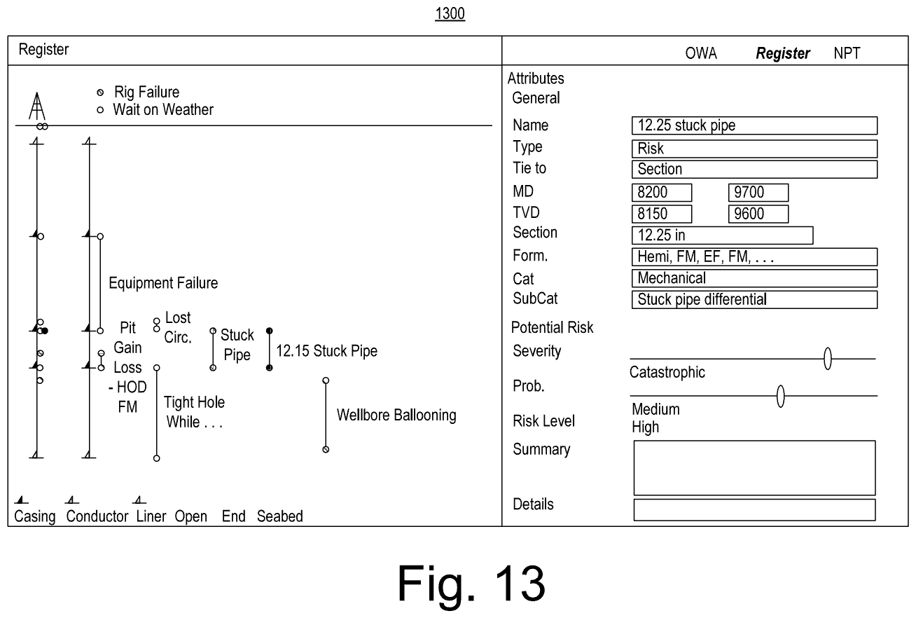

FIG. 13 shows an example of a GUI 1300 that includes various graphics for field operations. As shown, the GUI 1300 may include graphics representative of boreholes that may include one or more sections, portions, etc., which may be cased, open, etc. As shown, various risks may be identified with respect to borehole depth. For example, consider risks as to equipment failure, pit gain and/or loss, lost circulation, tight hole while tripping, stuck pipe, wellbore ballooning, etc. As an example, an event may be a rig failure event. As an example, a risk may be associated with weather and/or one or more other environmental conditions. As an example, environmental conditions may be related to precipitation, temperature, sunlight, darkness, wind, sea roughness, etc. As an example, where a site relies at least in part on solar power, a risk may exist due to weather, time of day, battery storage, grid access, etc. In the example GUI 1300, various graphics may be color coded, which may indicate probabilities and/or severity of risk. As an example, an open circle may represent a green color, a hatched circle may represent a yellow color, and a filled circle may represent a red color. As an example, the GUI 1300 may be operatively coupled to one or more other GUIs and/or information associated therewith. For example, consider information in the GUI 1300 as including information from one or more of the GUIs 500, 600, 700, 800, and 900.

As an example, a framework may be part of or operatively coupled to a planner (e.g., a planning framework). As an example, risks may be assessed during planning and/or execution of a plan. In the example GUI 1300, various graphics (e.g., circles, etc.) may be generated by a planner, for example, consider a planner that may access a risk assessment framework via one or more APIs. In such an example, the planner may make one or more API calls during planning to assess risk of one or more planned operations, which, in turn, may respond with risk information that may be taken into account by the planner. In such an approach, the planner may provide for plan generation in a manner that accounts for risks and that may provide for rendering of one or more GUIs with indicators as to risks. In such an example, field operations may be performed in a manner that is aware of risks.

As an example, during field operations, a framework may provide for assessing expected risks against actual risks. In such an approach, where the actual risks exceed expected risks, the framework may call for re-planning such that actual risk experience may be taken into account for revising a plan, for example, to drill a further portion of a borehole. For example, in the GUI 1300, consider the risk of equipment failure over a span of depths to be low; whereas, during actual drilling, equipment does fail. In such an example, as the difference between expected and actual may be sufficiently larger (e.g., according to one or more metrics), a framework may provide for triggering re-planning. As explained, a knowledge system may learn from experience where, for example, an experience may be for actual risk exceeding expected risk, or vice versa. In such an example, the knowledge system may provide for updating one or more risk relationships such that, given certain attributes, risk may be predicted in a more accurate manner.

In the example GUI 1300, various examples of attributes are indicated, which may include name, type, tie to, MD, TVD, section, formation, category, sub-category, etc. As an example, for a selected range of depths or event rendered graphically to the GUI 1300, the GUI 1300 may include a panel that shows potential risk severity, probability, etc. For example, severity may be minor, major, catastrophic, etc., while probability may be expressed using a scale, numbers and/or words. As an example, a framework may provide for output of a text that may be suitable for use as a summary and/or details. As explained, a framework may generate output with one or more links that may provide for linking to information in a database as to an underlying basis for a risk assessment. For example, consider a graphic that may indicate offset wells where the same or a similar issue was experienced during drilling, etc. In such an approach, a user may actuate a link to cause access to information for a historical event, for example, to determine the circumstances associated with that historical event and/or one or more remedial actions taken and/or consequences of the historical event and/or one or more remedial actions taken.

As explained, a framework may utilize an ontology-based approach to assessing risk, guiding authoring of descriptions, guiding authoring of queries, etc. As an example, a query field may be rendered to a GUI where a user may enter a prompt, which may concern an event or a risk of an event. As an example, a prompt may be related to one or more historical events such as, for example, “what did the driller do for that event when it happened at well XY?” In response, the framework may return an answer and/or a recommendation. For example, consider an answer that explains that the driller took an action that did not help and that, under the current circumstances, the framework recommends taking a different action or actions, which may be based on experiences at one or more other wells, review by of one or more incidents by an expert or a team, etc.

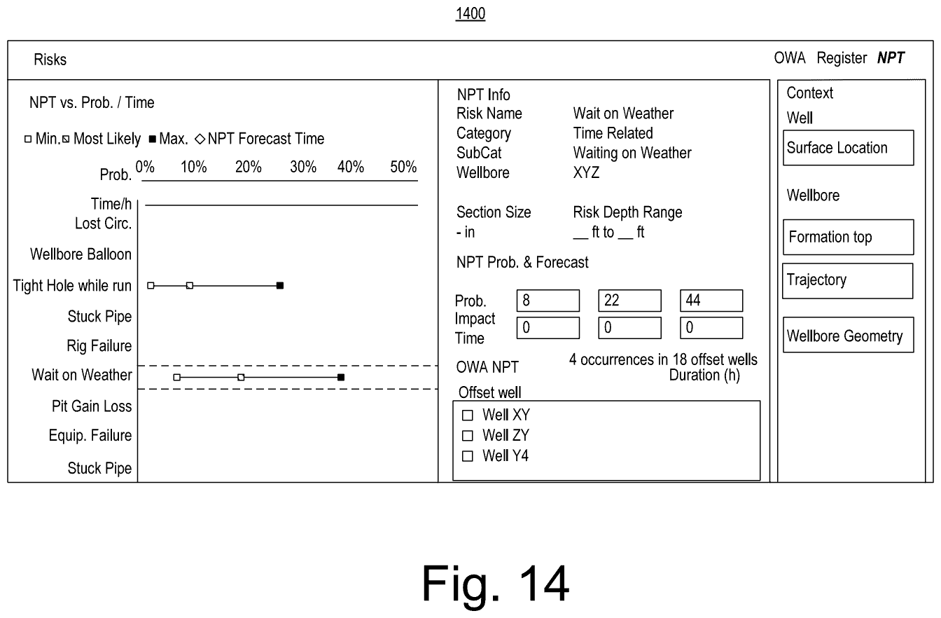

FIG. 14 shows an example of a GUI 1400 that includes various graphics associated with an assessment of non-productive time (NPT). The GUI 1400 may be associated with the GUI 1300, for example, via selection of an item in a menu (see, e.g., Register and NPT items).

As shown, the GUI 1400 may render graphics for different events with respect to time and/or probability. For example, consider events such as lost circulation, wellbore ballooning, tight hole while running in hole, stuck pipe, rig failure, wait on weather, pit gain or loss, etc. As shown, the wait on weather event has the greatest probability. As an example, an event may be selected such that information regarding the event appears in detail in another panel of the GUI 1400. For example, consider a panel that includes fields for attributes of an event, section size of a borehole, risk with respect to depth range, NPT probability and/or forecast, etc. As to probability, consider rendering of a minimum, a most likely and a maximum. As to impact time, consider rendering a minimum, a most likely and a maximum. As to offset well assessment (OWA), consider rendering information as to number of occurrences in offset wells such as, for example, “4 occurrences in 18 offset wells”. As to such offset well occurrences, the GUI 1400 may render a panel with graphical controls that may access information for one or more of the offset wells, which may include NPT information such as, for example, duration (e.g., NPT experienced). In such an approach, if one or more of the offset wells indicates a substantial duration, then an individual may understand that the event of interest may cause a substantial amount of NPT. In such an example, where a framework is integrated with or otherwise operatively coupled to a planner, the planner may generate a plan that aims to reduce risk of such an event to thereby reduce risk of experiencing substantial NPT during field operations. As an example, the GUI 1400 may be operatively coupled to one or more other GUIs and/or information associated therewith. For example, consider information in the GUI 1400 as including information from one or more of the GUIs 500, 600, 700, 800, and 900.

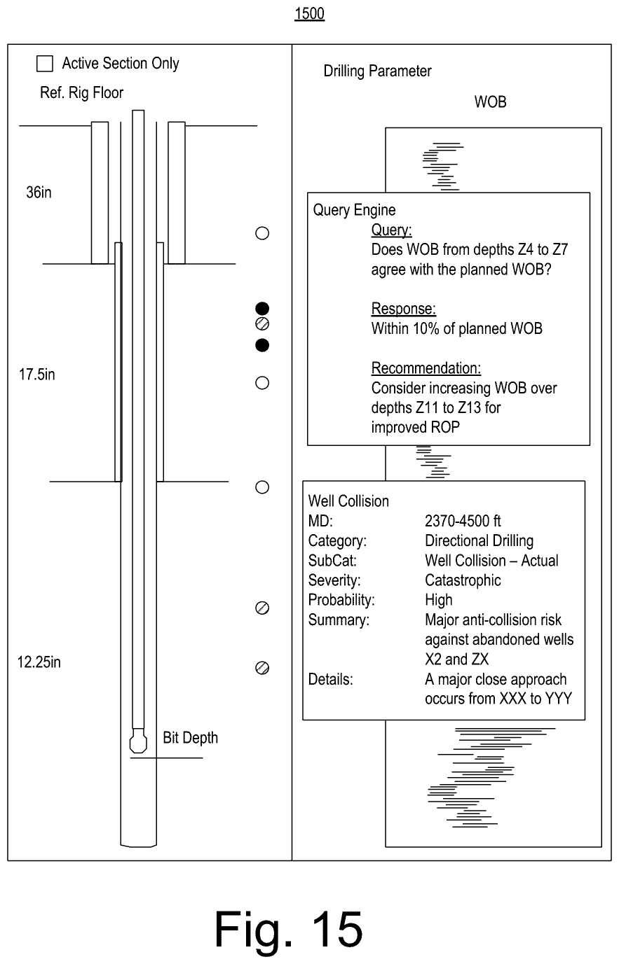

FIG. 15 shows an example of a GUI 1500 that includes various graphics associated with field operations for a site. As shown, a graphic may illustrate at least a portion of a borehole, as may be in part cased, etc. As an example, a drilling parameter panel may indicate past, planned, current, etc., parameter values with respect to depth.

As an example, the GUI 1500 may render a query engine graphic that may provide for entry of a query, rendering a response to the query and, for example, one or more recommendations. As shown, a query may be germane to one or more drilling parameters such as, for example, WOB, flow rate, ROP, rpm, etc. As an example, consider a query to determine whether actual WOB values correspond to planned WOB values. Such a query may be submitted as a prompt, etc., to a knowledge system that may return a response. As an example, where differences exist, that may be indicative of assessed risks per planned parameter values being less accurate. In such an example, a framework may provide for reassessing one or more risks, which may take into account actual parameter values where indicators as to reassessed risk may be rendered to the GUI 1500, which may result in changes to the GUI 1500 and/or one or more graphics rendered therewith. For example, a well collision panel is shown within the GUI 1500 that includes various details as to collision risk. Where such an update occurs, an individual may formulate a query for submission via the query engine to assess the risk and/or to generate one or more recommendations that may help to reduce or otherwise handle the risk.

As an example, the GUI 1500 may be dynamic and rendered in real-time with updates as field activities are performed. As an example, the GUI 1500 may provide for control of field equipment to improve field operations. As explained, such control may be based on recommendations from a framework that links to a knowledge system that operates at least in part according to an ontology. As an example, the GUI 1500 may be operatively coupled to one or more other GUIs and/or information associated therewith. For example, consider information in the GUI 1500 as including information from one or more of the GUIs 500, 600, 700, 800, and 900.

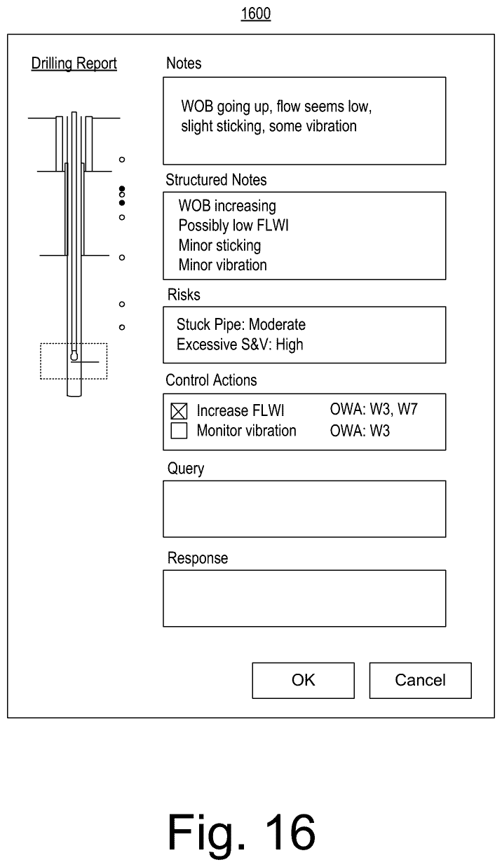

FIG. 16 shows an example of a GUI 1600 that may be utilized in real-time during field operations such as, for example, drilling operations. As shown, the GUI 1600 may provide for generation of a drilling report (e.g., a daily drilling report, etc.). As shown, the GUI 1600 may include a field for entering notes (e.g., comments, etc.) where such notes may be dynamically processed by features of a framework to assure compliance with grammar, states, data structuring, etc. In such an approach, the GUI 1600 may provide for rendering of structured notes. As shown, the GUI 1600 may also provide for assessment of risks and/or generation of control actions. In the example of FIG. 16, the GUI 1600 indicates that risks may exist for stuck pipe (e.g., as moderate) and for excessive shock and vibration (S&V) (e.g., as high). Such risks may be determined on the basis of inputting information, which may include structured notes, into a knowledge system. Such a knowledge system may provide for identifying one or more scenarios akin to the current scenario at a site where one or more control actions may be recommended according to one or more lessons learned from one or more other sites. As shown, a control action may be selectable for implementation, which may occur automatically, semi-automatically or manually. As an example, the GUI 1600 may provide for rendering of information as to past scenarios from one or more offset well analyses (OWAs), which may include providing links that may be actuated to cause rendering of details as to the one or more past scenarios. In such an approach, an individual and/or a machine may be provided with relevant information in a timely manner. As an example, the GUI 1600 may include a graphical control for entry of queries, for example, such as the GUI 1500. As shown, the GUI 1600 may include a graphical control for rendering of responses to queries. In such an approach, an individual may submit one or more queries for generating one or more corresponding responses via a knowledge system. In such an example, the individual may gain assurance as to one or more risks, control actions, etc., which may help to improve field operations (e.g., drilling, etc.).

As explained, a framework may utilize a knowledge system that may be ontology-based and that may provide for guided authoring. As explained, a framework may provide for structuring information from one or more sources to comport with a knowledge system schema. As explained, a framework may utilize natural language processing features, which may be applied to natural language entries (e.g., in real-time, from historical databases, etc.) and/or to machine language entries (e.g., to transform natural language to machine language and/or to transform machine language to natural language). As explained, a framework may provide for planning, re-planning, execution, etc., of field operations. As explained, a framework may improve reporting in a manner that may provide for problem solving as to actual and/or potential issues (e.g., events, etc.). As explained, an incident may be an event, which may be an actual event, a historical event or an event with a risk of occurrence at a present or future time.

As an example, a framework may include and/or be operatively coupled to one or more machine learning models, libraries, platforms, etc. For example, consider a framework that may provide for generation of and submission of prompts to a large language model (LLM). In such an example, an LLM may be utilized for one or more purposes. For example, an LLM may be utilized to generate an ontology, to generate classifications of an ontology, to process data (e.g., structured and/or unstructured) for an ontology, etc. As an example, an LLM may be operatively coupled to an ontology where, for example, a prompt to the LLM may provide for generation of a knowledge structure (e.g., a graph, etc.) where the LLM relies on an ontology and information from one or more data sources, which may include structured and/or unstructured data.

As an example, an ontology may represent concepts and relationships within a domain, for example, with an emphasis on shared understanding of semantics. As an example, a knowledge graph may be generated that represents knowledge using a graph structure, for example, with nodes and edges, which may connect nodes through relationships and attributes and facilitating flexible and interconnected data models.

While various language-based techniques and technologies are mentioned, a framework may include and/or be operatively coupled to one or more machine learning models that may provide for classification and/or prediction of events and/or control actions (e.g., remedial actions, preventive actions, etc.). As an example, one or more physics-based models may be utilized and/or one or more hybrid models (e.g., physics-based and data-driven).

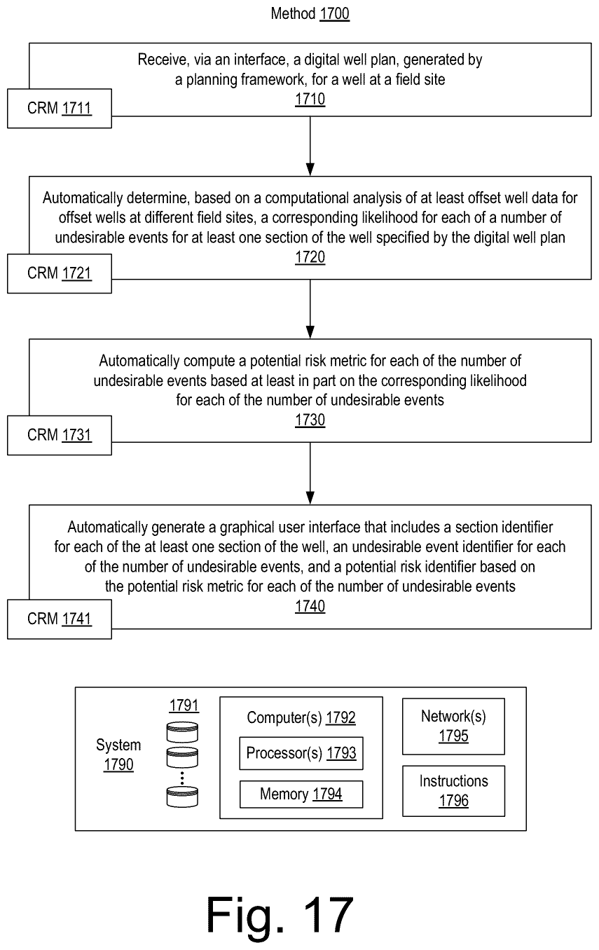

FIG. 17 shows an example of a method 1700 and an example of a system 1790. As shown, the method 1700 may include a reception block 1710 for receiving, via an interface, a digital well plan, generated by a planning framework, for a well at a field site; a determination block 1720 for automatically determining, based on a computational analysis of at least offset well data for offset wells at different field sites, a corresponding likelihood for each of a number of undesirable events for at least one section of the well specified by the digital well plan; a computation block 1730 for automatically computing a potential risk metric for each of the number of undesirable events based at least in part on the corresponding likelihood for each of the number of undesirable events; and a generation block 1740 for automatically generating a graphical user interface that includes a section identifier for each of the at least one section of the well, an undesirable event identifier for each of the number of undesirable events, and a potential risk identifier based on the potential risk metric for each of the number of undesirable events.

As explained, a framework may provide for uncovering risks that may be present within a digital well plan where such a framework may operate at least in part in an automated manner to generate a graphical user interface that includes identifiers as to risks. Such a framework may streamline planning, plan execution, etc., where, for example, field operations may be performed in an improved manner with less non-productive time (NPT). As explained, NPT may be associated with undesirable events, the risk thereof not being apparent to a visual review of a well plan by one or more humans. As explained, a framework may provide for leveraging offset well analyses to assess a digital well plan, for example, in an automated manner to highlight and/or uncover risks that may not be apparent upon visual inspection of a plan by a human. Such an approach may expedite planning, improve planning (e.g., plan generation), and improve field operations for a well at a field site (e.g., consider drilling a well in less time due to improved planning with respect to uncovered risks). As explained, a framework may provide for re-planning, which may account for one or more uncovered risks (e.g., one or more identifiers for one or more risks for one or more sections of a well, etc.).

FIG. 17 also shows various computer-readable media (CRM) blocks 1711, 1721, 1731, and 1741. Such blocks may include instructions that are executable by one or more processors, which may be one or more processors of a computational framework, a system, a computer, etc. A computer-readable medium may be a computer-readable storage medium that is not a signal, not a carrier wave and that is non-transitory. For example, a computer-readable medium may be a physical memory component that may store information in a digital format.

In the example of FIG. 17, a system 1790 includes one or more information storage devices 1791, one or more computers 1792, one or more networks 1795 and instructions 1796. As to the one or more computers 1792, each computer may include one or more processors (e.g., or processing cores) 1793 and memory 1794 for storing the instructions 1796, for example, executable by at least one of the one or more processors. As an example, a computer may include one or more network interfaces (e.g., wired or wireless), one or more graphics cards, a display interface (e.g., wired or wireless), etc. The system 1790 may be specially configured to perform one or more portions of the method 1700 of FIG. 17.

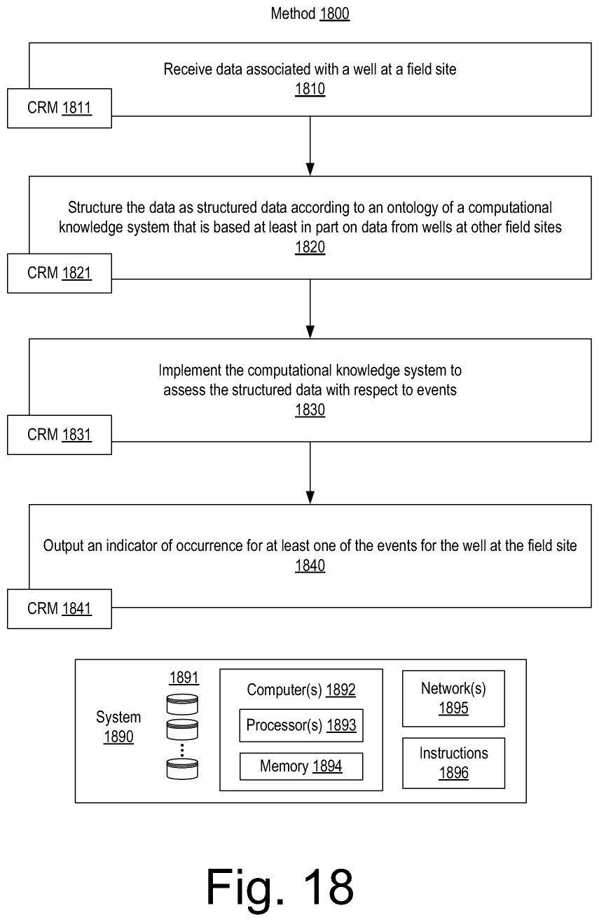

FIG. 18 shows an example of a method 1800 and an example of a system 1890. As shown, the method 1800 may include a reception block 1810 for receiving data associated with a well at a field site; a structure block 1820 for structuring the data as structured data according to an ontology of a computational knowledge system that is based at least in part on data from wells at other field sites; an implementation block 1830 for implementing the computational knowledge system to assess the structured data with respect to events; and an output block 1840 for outputting an indicator of occurrence for at least one of the events for the well at the field site.

FIG. 18 also shows various computer-readable media (CRM) blocks 1811, 1821, 1831, and 1841. Such blocks may include instructions that are executable by one or more processors, which may be one or more processors of a computational framework, a system, a computer, etc. A computer-readable medium may be a computer-readable storage medium that is not a signal, not a carrier wave and that is non-transitory. For example, a computer-readable medium may be a physical memory component that may store information in a digital format.

In the example of FIG. 18, a system 1890 includes one or more information storage devices 1891, one or more computers 1892, one or more networks 1895 and instructions 1896. As to the one or more computers 1892, each computer may include one or more processors (e.g., or processing cores) 1893 and memory 1894 for storing the instructions 1896, for example, executable by at least one of the one or more processors. As an example, a computer may include one or more network interfaces (e.g., wired or wireless), one or more graphics cards, a display interface (e.g., wired or wireless), etc. The system 1890 may be specially configured to perform one or more portions of the method 1800 of FIG. 18.

As explained, an ontology-led system may be implemented for root cause analysis. As explained, such a system may include a framework that includes a knowledge system or a framework that may be operatively coupled to a knowledge system (e.g., via one or more APIs, etc.). As an example, an ontology may relate to well construction processes and/or well production processes. As an example, one or more similarity measures may be defined on an ontology that may be utilized to recover a portfolio of examples similar to an input example, which may be a hypothetical example, an actual example, etc. As an example, guided authoring may be implemented, for example, via a guided description system that may assist individuals to capture information, which may be or include, for example, results from one or more well analyses (e.g., target well and/or one or more offset wells), observations during drilling as may be in a drilling report, observations during well testing as may be in a well testing report, etc. As an example, output of a framework and/or a system may include information with links and/or data. As an example, input and/or output may include knowledge derived from one or more root cause analyses. As explained, results from one or more root causes analyses (e.g., event or incidence analyses) may be captured in a structured manner leveraging an ontology-led system.

As an example, a computational framework and/or a computational knowledge system may include a solver, which may be implemented via executable instructions. For example, consider a computational framework and/or computational knowledge system that may include a processor and memory accessible to the processor where executable instructions may be stored in the memory and accessed for execution by the processor to cause the computational framework to perform one or more actions. Such a computational framework and/or computational knowledge system may include one or more interfaces for receipt of information and/or for output of information, which may include values of parameters, an instruction, etc. As an example, a computational framework and/or computational knowledge system may be part of a controller. As an example, a computational framework and/or computational knowledge system may be part of a system.

As an example, various systems, methods, etc., may implement one or machine learning models (ML models). For example, consider selection of undesirable events, determination of likelihood, determination of severity, etc., to be performed using one or more types of machine learning models. As an example, an ML model may be trained using data from one or more sources, which may include offset well data, data from a well being drilled, etc. An ML model may be a classification model, a prediction model, etc. As an example, an ML model may be implemented to classify various undesirable events by NPT such that a selection may be made as to which undesirable events to include for a section of a well as specified by a well plan. In such an example, a section of a well may be limited to a top number of NPT related undesirable events, which may be in excess of a certain number of hours as to NPT risk. As an example, a trained ML model may provide for predicting NPT risk such as how may NPT hours may be realized if an undesirable event actually occurs for a planned well. Such an approach may utilize various feature inputs as may be determined using offset well data such that feature inputs may be extracted from a digital well plan (e.g., or a portion thereof) to predict NPT hours, which may be a specific number or a range, optionally along with one or more probability values.

As to types of ML models, consider one or more of a support vector machine (SVM) model, a k-nearest neighbors (KNN) model, an ensemble classifier model, a neural network (NN) model, etc. As an example, a machine learning model may be a deep learning model (e.g., deep Boltzmann machine, deep belief network, convolutional neural network, stacked auto-encoder, etc.), an ensemble model (e.g., random forest, gradient boosting machine, bootstrapped aggregation, AdaBoost, stacked generalization, gradient boosted regression tree, etc.), a neural network model (e.g., radial basis function network, perceptron, back-propagation, Hopfield network, etc.), a regularization model (e.g., ridge regression, least absolute shrinkage and selection operator, elastic net, least angle regression), a rule system model (e.g., cubist, one rule, zero rule, repeated incremental pruning to produce error reduction), a regression model (e.g., linear regression, ordinary least squares regression, stepwise regression, multivariate adaptive regression splines, locally estimated scatterplot smoothing, logistic regression, etc.), a Bayesian model (e.g., naïve Bayes, average on-dependence estimators, Bayesian belief network, Gaussian naïve Bayes, multinomial naïve Bayes, Bayesian network), a decision tree model (e.g., classification and regression tree, iterative dichotomiser 3, C4.5, C5.0, chi-squared automatic interaction detection, decision stump, conditional decision tree, M5), a dimensionality reduction model (e.g., principal component analysis, partial least squares regression, Sammon mapping, multidimensional scaling, projection pursuit, principal component regression, partial least squares discriminant analysis, mixture discriminant analysis, quadratic discriminant analysis, regularized discriminant analysis, flexible discriminant analysis, linear discriminant analysis, etc.), an instance model (e.g., k-nearest neighbor, learning vector quantization, self-organizing map, locally weighted learning, etc.), a clustering model (e.g., k-means, k-medians, expectation maximization, hierarchical clustering, etc.), etc.

As an example, a system may utilize one or more recurrent neural networks (RNNs). One type of RNN is referred to as long short-term memory (LSTM), which may be a unit or component (e.g., of one or more units) that may be in a layer or layers. A LSTM component may be a type of artificial neural network (ANN) designed to recognize patterns in sequences of data, such as time series data. When provided with time series data, LSTMs take time and sequence into account such that an LSTM may include a temporal dimension. For example, consider utilization of one or more RNNs for processing temporal data from one or more sources, optionally in combination with spatial data. Such an approach may recognize temporal patterns, which may be utilized for making predictions (e.g., as to a pattern or patterns for future times, etc.).

As an example, the TENSORFLOW framework (Google LLC, Mountain View, California) may be implemented, which is an open-source software library for dataflow programming that includes a symbolic math library, which may be implemented for machine learning applications that may include neural networks. As an example, the CAFFE framework may be implemented, which is a DL framework developed by Berkeley Al Research (BAIR) (University of California, Berkeley, California). As another example, consider the SCIKIT platform (e.g., scikit-learn), which utilizes the PYTHON programming language. As an example, a framework such as the APOLLO AI framework may be utilized (APOLLO.AI GmbH, Germany). As mentioned, a framework such as the PYTORCH framework may be utilized.

As an example, a training method may include various actions that may operate on a dataset to train a ML model. As an example, a dataset may be split into training data and test data where test data may provide for evaluation. A method may include cross-validation of parameters and best parameters, which may be provided for model training.

The TENSORFLOW framework may run on multiple CPUs and GPUs (with optional CUDA (NVIDIA Corp., Santa Clara, California) and SYCL (The Khronos Group Inc., Beaverton, Oregon) extensions for general-purpose computing on graphics processing units (GPUs)). TENSORFLOW is available on 64-bit LINUX, MACOS (Apple Inc., Cupertino, California), WINDOWS (Microsoft Corp., Redmond, Washington), and mobile computing platforms including ANDROID (Google LLC, Mountain View, California) and IOS (Apple Inc.) operating system-based platforms.

TENSORFLOW computations may be expressed as stateful dataflow graphs; noting that the name TENSORFLOW derives from the operations that such neural networks perform on multidimensional data arrays. Such arrays may be referred to as “tensors”.

As an example, a foundational GPT model may be utilized and/or further adapted to produce more knowledge systems directed to specific tasks and/or subject-matter domains. Techniques for adaptation may include additional fine-tuning (e.g., beyond tuning of a foundation model, etc.), certain forms of prompt engineering, etc. As an example, a large language model (LLM) may be a chatbot type of LLM. For example, consider the OpenAI ChatGPT LLM, which is an online chat interface powered by an instruction-tuned language model trained in a similar fashion to InstructGPT. Other chatbots may include features of GPT-4 (OpenAI), Bard (e.g., LaMDA family of conversation-trained language models, PaLM, etc.) (Google, Mountain View, California), etc.

As an example, a LLM Meta AI (LLAMA) LLM may be utilized, which includes a transformer architecture; noting some architectural differences compared to GPT-3. For example, LLAMA utilizes the SwiGLU activation function rather than ReLU, uses rotary positional embeddings rather than absolute positional embedding, and uses root-mean-squared layer-normalization rather than standard layer-normalization. Further, there may be an increase in context length from 2K (Llama 1) tokens to 4K (Llama 2) tokens between.

As an example, a knowledge system (e.g., a knowledge-based system, etc.) may be considered an intelligent system that may totally or partially involve computational representation and processing of knowledge. As explained, a workflow may include engineering and development of a knowledge system. As an example, various computational structures may be utilized for knowledge representation. As an example, various procedures may be utilized for one or more of computational processing; automated reasoning, and inference from knowledge; learning new knowledge; handling uncertainty in information; generation of knowledge-based decision networks; coupling distributed knowledge systems; etc.

As an example, a framework and/or a knowledge system may utilize knowledge representation in first-order logic, matching and/or unification of first-order logic formulas; rule-based expert systems, rule firing, and/or forward and backward chaining; automated planning and problem-solving, total-order problem solvers, least-commitment planning, and/or hierarchical problem solving; search methods, depth-first search, breadth-first search, heuristic search, greedy search, A* algorithms, and/or hill climbing; structured knowledge representation (e.g., representing knowledge using frames, objects and semantic networks; first-order logic correspondence; matching; inheritance; defaults; and/or automated inference): constraints, constraint networks, constraint satisfaction, node and arc consistency, compound labeling, constraint satisfaction algorithms, problem reduction, back jumping, interval constraints, interval calculus, and/or algorithms for interval constraint satisfaction.

As an example, a method may include receiving, via an interface, a digital well plan, generated by a planning framework, for a well at a field site; automatically determining, based on a computational analysis of at least offset well data for offset wells at different field sites, a corresponding likelihood for each of a number of undesirable events for at least one section of the well specified by the digital well plan; automatically computing a potential risk metric for each of the number of undesirable events based at least in part on the corresponding likelihood for each of the number of undesirable events; and automatically generating a graphical user interface that includes a section identifier for each of the at least one section of the well, an undesirable event identifier for each of the number of undesirable events, and a potential risk identifier based on the potential risk metric for each of the number of undesirable events. In such an example, the method may include automatically determining, based on the, a corresponding severity for each of a number of undesirable events for at least one section of the well where, for example, computing the potential risk metric for one of the number of undesirable events includes multiplying the corresponding likelihood by the corresponding severity.

As an example, a method may include triggering a planning framework to generate a revised digital well plan based at least in part on a potential risk metric for one of a number of undesirable events. In such an example, triggering may occur responsive to feedback received via the graphical user interface and/or via an automated analysis of the potential risk metric.

As an example, a method may include determining a number of undesirable events using a non-productive time analysis. In such an example, a non-productive time analysis may select the number of undesirable events based on a non-productive time threshold. For example, consider the number of undesirable events as being selected based on corresponding non-productive times exceeding the non-productive time threshold. In such an example, the non-productive time threshold may be greater than 10 hours (e.g., consider an NPT threshold of 20 hours, 50 hours, 100 hours, etc.).

As an example, a corresponding likelihood for at least one of a number of undesirable events may be determined based on field data acquired for a drilling operation for at least one prior section of a well. For example, consider a well where field data from an intermediate section may inform likelihood determination for a curved section and/or a curved section for a horizontal section. In such an approach, a framework may continually update likelihoods as drilling progresses from one section to another section or, for example, within a section as field data from drilling stands may be acquired to inform drilling of additional stands.

As an example, a potential risk identifier may include one or more of a numeric value and a color. For example, consider a number with a background that is a color or a colored number.

As an example, a method may include associating each of a number of undesirable events with a role in a hierarchy of roles based at least in part on a potential risk metric for each of the number of undesirable events. In such an example, the hierarchy may include at least three roles. As an example, a method may include transmitting a graphical user interface to network destinations that correspond to roles in a hierarchy. In such an example, the method may include scheduling a review time for the roles for review of content of the graphical user interface. For example, consider accessing calendar information, work schedule information, etc., to coordinate review of content of a graphical user interface. As an example, a method may include, after a review time, responsive to input received via a graphical user interface, transmitting a digital well plan to a drilling framework for execution of the digital well plan. As explained, frameworks may be integrated into framework environment (e.g., the DELFI environment, etc.).

As an example, a number of undesirable events may include one or more of a loss and stuck pipe. Some examples of undesirable events are shown in the GUIs 500 and 600. As explained, such events may be determined on the basis of potential to introduce NPT.

As an example, a digital well plan may be or include a digital well plan for directional drilling where at least one section of a well may be one or more of a surface section, an intermediate section, a curved section, and a horizontal section. In such an example, each section may utilize different equipment (e.g., BHAs) that are suited to particular drilling (e.g., vertical, curved, horizontal, etc.).

As an example, a system may include one or more processors; memory accessible to at least one of the one or more processors; processor-executable instructions stored in the memory and executable to instruct the system to: receive a digital well plan, generated by a planning framework, for a well at a field site; automatically determine, based on a computational analysis of at least offset well data for offset wells at different field sites, a corresponding likelihood for each of a number of undesirable events for at least one section of the well specified by the digital well plan; automatically compute a potential risk metric for each of the number of undesirable events based at least in part on the corresponding likelihood for each of the number of undesirable events; and automatically generate a graphical user interface that includes a section identifier for each of the at least one section of the well, an undesirable event identifier for each of the number of undesirable events, and a potential risk identifier based on the potential risk metric for each of the number of undesirable events.

As an example, one or more computer-readable storage media may include processor-executable instructions to instruct a computing system to: receive a digital well plan, generated by a planning framework, for a well at a field site; automatically determine, based on a computational analysis of at least offset well data for offset wells at different field sites, a corresponding likelihood for each of a number of undesirable events for at least one section of the well specified by the digital well plan; automatically compute a potential risk metric for each of the number of undesirable events based at least in part on the corresponding likelihood for each of the number of undesirable events; and automatically generate a graphical user interface that includes a section identifier for each of the at least one section of the well, an undesirable event identifier for each of the number of undesirable events, and a potential risk identifier based on the potential risk metric for each of the number of undesirable events.

As an example, a method may include receiving data associated with a well at a field site; structuring the data as structured data according to an ontology of a computational knowledge system that is based at least in part on data from wells at other field sites; implementing the computational knowledge system to assess the structured data with respect to events; and outputting an indicator of occurrence for at least one of the events for the well at the field site. In such an example, the events may include undesirable events. As an example, each of a number of undesirable events may be associated with non-productive time with respect to field operations for a well at a field site.

As an example, an indicator of occurrence may be or include a probability of occurrence. As an example, an indicator of occurrence may be or include a severity of occurrence. As an example, a method may include outputting that outputs multiple indicators of occurrence, where the multiple indicators of occurrence may include a probability of occurrence and a severity of occurrence.

As an example, data may include text data received via a graphical user interface (e.g., consider data entered via use of a keyboard, a microphone and voice recognition, etc.). In such an example, a method may include implementing guided authoring to tailor input of the text data. As an example, a graphical user interface may be a drilling report interface for entry of text data associated field operations for a well at a field site. In such an example, the graphical user interface may include a graphical field for rendering at least an indicator of occurrence for at least one event for a well at a field site.

As an example, a method may include outputting that outputs an indicator of occurrence with one or more links that link to at least a portion of data from one or more wells at other field sites (e.g., with reference to a target well at a field site).

As an example, a method may include structuring that includes extracting one or more states from data, where, for example, each of the states relates to a possible state of a well at a field site.

As an example, a method may include building at least part of a computational knowledge system via processing of investigated events for one or more wells at other field sites. In such an example, investigated events may include associated causes. For example, consider associated causes that may include one or more of root causes and immediate causes.

As an example, data associated with a well at a field site may include planning data generated by a planner that operates to generate a digital well plan for the well at the field site. As an example, a method may operate to trigger re-planning. For example, consider a risk assessment that may trigger re-planning. In such an example, a risk assessment may be for expected risk in view of actual risk (e.g., consider occurrence of one or more undesirable events during one or more field operations). In such an approach, re-planning may provide for reassessment of risk in view of undesirable events that may have occurred at a well.

As an example, data associated with a well at a field site may include operational data associated with one or more field operations performed for the well at the field site. For example, a method may be implemented as a dynamic real-time method that includes receiving operational data, which may include sensor-based data and/or data entered by an individual via a graphical user interface (e.g., a drilling report interface, a drilling operations framework interface, etc.).

As an example, a method may include outputting at least one control action to reduce risk of occurrence of one or more events for a well at a field site. As explained, a method may include generating a recommended action, which may be a remedial action, a preventive action, etc. In such an approach, an action may be transmitted to a controller that controls field equipment for performing field operations.

As an example, a system may include one or more processors; memory accessible to at least one of the one or more processors; and processor-executable instructions stored in the memory and executable to instruct the system to: receive data associated with a well at a field site; structure the data as structured data according to an ontology of a computational knowledge system that is based at least in part on data from wells at other field sites; implement the computational knowledge system to assess the structured data with respect to events; and output an indicator of occurrence for at least one of the events for the well at the field site.

As an example, one or more computer-readable storage media may include processor-executable instructions to instruct a computing system to: receive data associated with a well at a field site; structure the data as structured data according to an ontology of a computational knowledge system that is based at least in part on data from wells at other field sites; implement the computational knowledge system to assess the structured data with respect to events; and output an indicator of occurrence for at least one of the events for the well at the field site.

As an example, a computer program product that may include computer-executable instructions to instruct a computing system to perform one or more methods such as one or more of the methods described herein (e.g., in part, in whole and/or in various combinations).

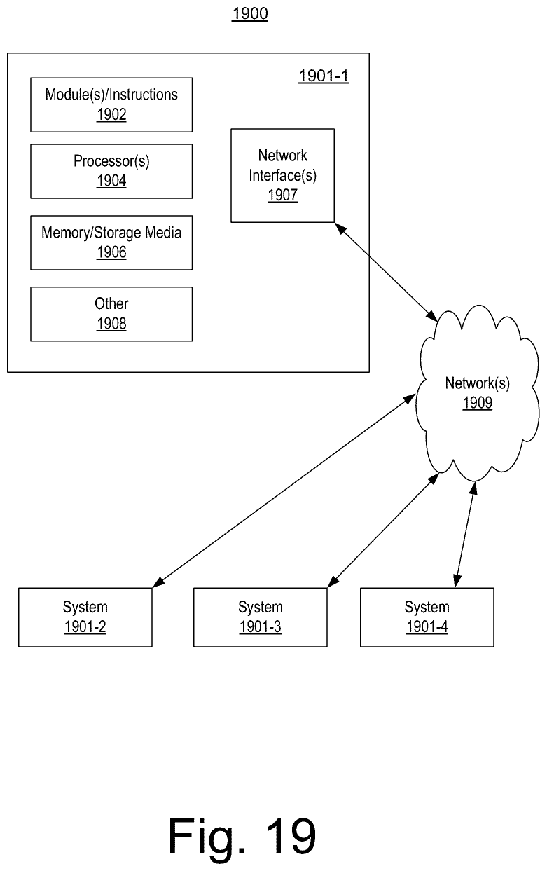

In some embodiments, a method or methods may be executed by a computing system. FIG. 19 shows an example of a system 1900 that may include one or more computing systems 1901-1, 1901-2, 1901-3 and 1901-4, which may be operatively coupled via one or more networks 1909, which may include wired and/or wireless networks.

As an example, a system may include an individual computer system or an arrangement of distributed computer systems. In the example of FIG. 19, the computer system 1901-1 may include one or more modules 1902, which may be or include processor-executable instructions, for example, executable to perform various tasks (e.g., receiving information, requesting information, processing information, simulation, outputting information, etc.).

As an example, a module may be executed independently, or in coordination with, one or more processors 1904, which is (or are) operatively coupled to one or more storage media 1906 (e.g., via wire, wirelessly, etc.). As an example, one or more of the one or more processors 1904 may be operatively coupled to at least one of one or more network interface 1907. In such an example, the computer system 1901-1 may transmit and/or receive information, for example, via the one or more networks 1909 (e.g., consider one or more of the Internet, a private network, a cellular network, a satellite network, etc.). As shown, one or more other components 1908 may be included in the computer system 1901-1.

As an example, the computer system 1901-1 may receive from and/or transmit information to one or more other devices, which may be or include, for example, one or more of the computer systems 1901-2, etc. A device may be located in a physical location that differs from that of the computer system 1901-1. As an example, a location may be, for example, a processing facility location, a data center location (e.g., server farm, etc.), a rig location, a wellsite location, a downhole location, etc.

As an example, a processor may be or include a microprocessor, microcontroller, processor module or subsystem, programmable integrated circuit, programmable gate array, or another control or computing device.

As an example, the storage media 1906 may be implemented as one or more computer-readable or machine-readable storage media. As an example, storage may be distributed within and/or across multiple internal and/or external enclosures of a computing system and/or additional computing systems.

As an example, a storage medium or storage media may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLUERAY disks, or other types of optical storage, or other types of storage devices.

As an example, a storage medium or media may be located in a machine running machine-readable instructions, or located at a remote site from which machine-readable instructions may be downloaded over a network for execution.

As an example, various components of a system such as, for example, a computer system, may be implemented in hardware, software, or a combination of both hardware and software (e.g., including firmware), including one or more signal processing and/or application specific integrated circuits.

As an example, a system may include a processing apparatus that may be or include a general-purpose processors or application specific chips (e.g., or chipsets), such as ASICs, FPGAs, PLDs, or other appropriate devices.

As an example, a device may be a mobile device that includes one or more network interfaces for communication of information. For example, a mobile device may include a wireless network interface (e.g., operable via IEEE 802.11, ETSI GSM, BLUETOOTH, satellite, etc.). As an example, a mobile device may include components such as a main processor, memory, a display, display graphics circuitry (e.g., optionally including touch and gesture circuitry), a SIM slot, audio/video circuitry, motion processing circuitry (e.g., accelerometer, gyroscope), wireless LAN circuitry, smart card circuitry, transmitter circuitry, GPS circuitry, and a battery. As an example, a mobile device may be configured as a cell phone, a tablet, etc. As an example, a method may be implemented (e.g., wholly or in part) using a mobile device. As an example, a system may include one or more mobile devices.

As an example, a system may be a distributed environment, for example, a so-called “cloud” environment where various devices, components, etc. interact for purposes of data storage, communications, computing, etc. As an example, a device or a system may include one or more components for communication of information via one or more of the Internet (e.g., where communication occurs via one or more Internet protocols), a cellular network, a satellite network, etc. As an example, a method may be implemented in a distributed environment (e.g., wholly or in part as a cloud-based service).

As an example, information may be input from a display (e.g., consider a touchscreen), output to a display or both. As an example, information may be output to a projector, a laser device, a printer, etc. such that the information may be viewed. As an example, information may be output stereographically or holographically. As to a printer, consider a 2D or a 3D printer. As an example, a 3D printer may include one or more substances that may be output to construct a 3D object. For example, data may be provided to a 3D printer to construct a 3D representation of a subterranean formation. As an example, layers may be constructed in 3D (e.g., horizons, etc.), geobodies constructed in 3D, etc. As an example, holes, fractures, etc., may be constructed in 3D (e.g., as positive structures, as negative structures, etc.).

Although only a few examples have been described in detail above, those skilled in the art will readily appreciate that many modifications are possible in the examples. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures.

What is claimed is:

1. A method comprising:
receiving data associated with a well at a field site;
structuring the data as structured data according to an ontology of a computational knowledge system that is based at least in part on data from wells at other field sites;
implementing the computational knowledge system to assess the structured data with respect to events; and
outputting an indicator of occurrence for at least one of the events for the well at the field site.

2. The method of claim 1, wherein the events comprise undesirable events.

3. The method of claim 2, wherein each of the undesirable events is associated with non-productive time with respect to field operations for the well at the field site.

4. The method of claim 1, wherein the indicator of occurrence comprises a probability of occurrence.

5. The method of claim 1, wherein the indicator of occurrence comprises a severity of occurrence.

6. The method of claim 1, wherein the outputting outputs multiple indicators of occurrence, wherein the multiple indicators of occurrence comprise a probability of occurrence and a severity of occurrence.

7. The method of claim 1, wherein the data comprise text data received via a graphical user interface.

8. The method of claim 7, comprising implementing guided authoring to tailor input of the text data.

9. The method of claim 7, wherein the graphical user interface comprises a drilling report interface for entry of text data associated field operations for the well at the field site.

10. The method of claim 9, wherein the graphical user interface comprises a graphical field for rendering at least the indicator of occurrence for the at least one of the events for the well at the field site.

11. The method of claim 1, wherein the outputting outputs the indicator of occurrence with one or more links that link to at least a portion of the data from one or more of the wells at the other field sites.

12. The method of claim 1, wherein the structuring comprises extracting one or more states from the data, wherein each of the states relates to a possible state of the well at the field site.

13. The method of claim 1, comprising building at least part of the computational knowledge system via processing of investigated events for one or more of the wells at the other field sites.

14. The method of claim 13, wherein the investigated events comprise associated causes.

15. The method of claim 14, wherein the associated causes comprise one or more of root causes and immediate causes.

16. The method of claim 1, wherein the data associated with the well at the field site comprises planning data generated by a planner that operates to generate a digital well plan for the well at the field site.

17. The method of claim 1, wherein the data associated with the well at the field site comprises operational data associated with one or more field operations performed for the well at the field site.

18. The method of claim 1, further comprising outputting at least one control action to reduce risk of occurrence of one or more of the events for the well at the field site.

19. A system comprising:
one or more processors;
memory accessible to at least one of the one or more processors; and
processor-executable instructions stored in the memory and executable to instruct the system to:
receive data associated with a well at a field site;
structure the data as structured data according to an ontology of a computational knowledge system that is based at least in part on data from wells at other field sites;
implement the computational knowledge system to assess the structured data with respect to events; and
output an indicator of occurrence for at least one of the events for the well at the field site.

20. One or more computer-readable storage media comprising processor-executable instructions to instruct a computing system to:
receive data associated with a well at a field site;
structure the data as structured data according to an ontology of a computational knowledge system that is based at least in part on data from wells at other field sites;
implement the computational knowledge system to assess the structured data with respect to events; and
output an indicator of occurrence for at least one of the events for the well at the field site.
